(19) United States
(12) Patent Application Publication
(10) Pub. No.: US 2025/0126916 A1
(43) Pub. Date: Apr. 17, 2025

(54) IMAGE SENSOR AND FABRICATION METHOD OF THE SAME

(71) Applicant: SAMSUNG ELECTRONICS CO., LTD., Suwon-si (KR)

(72) Inventors: KOOK TAE KIM, Suwon-si (KR); JINGYUN KIM, Suwon-si (KR); MINKYUNG LEE, Suwon-si (KR)

(73) Assignee: SAMSUNG ELECTRONICS CO., LTD., Suwon-si (KR)

(21) Appl. No.: 18/650,969

(22) Filed: Apr. 30, 2024

(30) Foreign Application Priority Data
Oct. 13, 2023 (KR) 10-2023-0137157

(51) Int. Cl. H01L 27/146

(52) U.S. Cl. CPC H10F 39/807; H10F 39/8063; H10F 39/811

(57) ABSTRACT

An image sensor is provided. The image sensor includes: a plurality of pixels; a semiconductor substrate including a first surface and a second surface opposing the first surface; a device isolation layer provided in a trench penetrating through the first surface and the second surface of the semiconductor substrate, and separating the plurality of pixels from each other; and a microlens provided on the second surface. The device isolation layer includes: a buried insulating pattern penetrating through the first surface and the second surface; an insulating liner between the buried insulating pattern and the semiconductor substrate; a conductive liner between the insulating liner and the buried insulating pattern; and a buried conductive pattern provided on at least a portion of the buried insulating pattern and contacting the conductive liner.

### CROSS-REFERENCE TO RELATED APPLICATION

This application claims priority to Korean Patent Application No. 10-2023-0137157, filed on Oct. 13, 2023, in the Korean Intellectual Property Office, the disclosure of which is incorporated by reference herein in its entirety.

### BACKGROUND

The present disclosure relates to an image sensor and a method of fabricating the same.

An image sensor may include a plurality of pixels that are two-dimensionally arranged. Each of the pixels may include a photodiode, which acts as a photoelectric conversion element, and a device isolation layer between photoelectric conversion elements to separate the photoelectric conversion elements from each other. The device isolation layer may exhibit a light absorption effect depending on a material thereof. Therefore, when light is absorbed on a light-incident side, the intensity of light entering the photoelectric conversion elements may be reduced.

### SUMMARY

One or more example embodiments provide an image sensor for significantly reducing optical loss to increase photoelectric conversion efficiency.

One or more example embodiments provide an image sensor for significantly reducing defects, such as dark current, to quality of the image sensor while significantly reducing optical loss.

According to an aspect of an example embodiment, an image sensor includes: a plurality of pixels; a semiconductor substrate including a first surface and a second surface opposing the first surface; a device isolation layer provided in a trench penetrating through the first surface and the second surface of the semiconductor substrate, and separating the plurality of pixels from each other; and a microlens provided on the second surface. The device isolation layer includes: a buried insulating pattern penetrating through the first surface and the second surface; an insulating liner between the buried insulating pattern and the semiconductor substrate; a conductive liner between the insulating liner and the buried insulating pattern; and a buried conductive pattern provided on at least a portion of the buried insulating pattern and contacting the conductive liner.

According to another aspect of an example embodiment, an image sensor includes: a plurality of pixels arranged in a matrix; a semiconductor substrate including a first surface and a second surface opposing the first surface, wherein the second surface is provided as a light-incident surface; and a device isolation layer provided within a trench penetrating through the first surface and the second surface of the semiconductor substrate, and separating the plurality of pixels from each other. The device isolation layer includes side portions, extending in a row direction and a column direction, and intersection portions provided at regions in which the side portions intersect each other. Each of the intersection portions includes: a buried insulating pattern penetrating through the first surface and the second surface; an insulating liner between the buried insulating pattern and the semiconductor substrate; a conductive liner between the insulating liner and the buried insulating pattern; and a buried conductive pattern provided on the buried insulating pattern and contacting the conductive liner.

According to another aspect of an example embodiment, an image sensor includes: a plurality of pixels arranged in a matrix; a semiconductor substrate including a first surface and a second surface opposing the first surface; a device isolation layer provided within a trench penetrating through the first surface and the second surface of the semiconductor substrate to separate the plurality of pixels from each other, and including side portions and intersection portions, the side portions extending in a row direction and a column direction, and the intersection portions being in regions in which the side portions intersect each other; and a microlens provided on the second surface. The device isolation layer includes: a buried insulating pattern penetrating through the first surface and the second surface; an insulating liner between the buried insulating pattern and the semiconductor substrate; a conductive liner between the insulating liner and the buried insulating pattern; and a buried conductive pattern provided on at least a portion of the buried insulating pattern and contacting the conductive liner. The buried conductive pattern is provided in at any one or any combination of the side portions and the intersection portions.

### BRIEF DESCRIPTION OF DRAWINGS

The above and other aspects and features will be more apparent from the following description of example embodiments, taken in conjunction with the accompanying drawings.

FIG. 1 is a block diagram of an image sensor according to example embodiments.

FIG. 2 is a circuit diagram of a pixel array of an image sensor according to example embodiments.

FIG. 3 is a plan view of an image sensor according to example embodiments.

FIG. 4 is a cross-sectional view corresponding to line I-I′ of FIG. 3.

FIG. 5 is a plan view of an image sensor according to an example embodiment when viewed from above, and corresponds to P1 of FIG. 3.

FIG. 6 includes cross-sectional views taken along lines IIa-IIa′, IIb-IIb′, and IIc-IIc′ of FIG. 5.

FIGS. 7A, 7B, and 7C are enlarged cross-sectional views of P2a, P2b, and P2c of FIG. 6, respectively.

FIG. 8 is a plan view of the image sensor according to an example embodiment when viewed from above, and corresponds to P1 of FIG. 3.

FIG. 9 is a cross-sectional view showing a cross section along lines IIa-IIa′, IIb-IIb′, and IIc-IIc′ of FIG. 8.

FIGS. 10A, 10B, and 10C are enlarged cross-sectional views of P2a, P2b, and P2c of FIG. 9, respectively.

FIG. 11 is a plan view of an image sensor according to an example embodiment when viewed from above, and corresponds to P1 of FIG. 3.

FIG. 12 includes cross-sectional views taken along lines IIa-IIa′, IIb-IIb′, and IIc-IIc′ of FIG. 11.

FIGS. 13A, 13B, and 13C are enlarged cross-sectional views of P2a, P2b, and P2c of FIG. 12, respectively.

FIG. 14 is a plan view of an image sensor according to an example embodiment when viewed from above, and corresponds to P1 of FIG. 3.

FIG. 15 includes cross-sectional views taken along lines IIa-IIa′, IIb-IIb′, and IIc-IIc′ of FIG. 14.

FIGS. 16A, 16B, and 16C are enlarged cross-sectional views of P2a, P2b, and P2c of FIG. 15, respectively.

FIG. 17 is a plan view of an image sensor according to an example embodiment when viewed from above, and corresponds to P1 of FIG. 3.

FIG. 18 includes cross-sectional views taken along lines IIa-IIa′, IIb-IIb′, and IIc-IIc′ of FIG. 17.

FIGS. 19A, 19B, and 19C are enlarged cross-sectional views of P2a, P2b, and P2c of FIG. 18, respectively.

FIGS. 20A, 20B, 20C, 20D, 20E, 20F, 20G, 20H, 20I, 20J, 20K and 20L are cross-sectional views, sequentially illustrating a process of fabricating an image sensor according to an example embodiment.

FIGS. 21A, 21B, 21C, 21D, 21E, 21F and 21G are cross-sectional views illustrating a method of fabricating an image sensor according to an example embodiment.

### DETAILED DESCRIPTION

The present disclosure may be modified in various ways, and may have various embodiments, among which specific embodiments will be described in detail with reference to the accompanying drawings. However, it should be understood that the description of the specific embodiments of the present disclosure is not intended to limit the present disclosure to a particular mode of practice, and that the present disclosure is to cover all modifications, equivalents, and substitutes included in the spirit and technical scope of the present disclosure.

Hereinafter, example embodiments will be described in detail with reference to the attached drawings. Like reference numerals in the drawings denote like elements, and redundant descriptions thereof will be omitted. Each example embodiment provided in the following description is not excluded from being associated with one or more features of another example or another example embodiment also provided herein or not provided herein but consistent with the present disclosure. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation

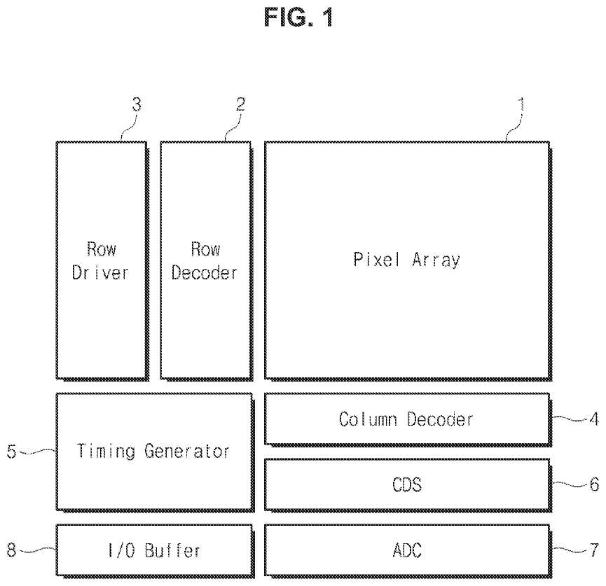

FIG. 1 is a schematic block diagram of an image sensor according to example embodiments.

Referring to FIG. 1, an image sensor according to an example embodiment may include a pixel array 1, a row decoder 2, a row driver 3, and a column decoder 4, a timing generator 5, a correlated double sampler (CDS) 6, an analog-to-digital converter (ADC) 7, and an input/output buffer (I/O Buffer) 8.

The pixel array 1 may include a plurality of pixels that are two-dimensionally arranged, and may convert optical signals into electrical signals. The pixel array 1 may be driven by a plurality of driving signals such as a pixel select signal, a reset signal, and a charge transfer signal from the row driver 3. In addition, the converted electrical signals may be provided to the correlated double sampler 6.

The row driver 3 may provide a plurality of driving signals to the pixel array 1 to drive a plurality of pixels based on a decoded result from the row decoder 2. When pixels are arranged in a matrix form, the driving signals may be provided for each row.

The timing generator 5 may provide a timing signal and a control signal to the row decoder 2 and the column decoder 4.

The correlated double sampler 6 may receive, hold, and sample the electrical signal generated by the pixel array 1. The correlated double sampler 6 may perform a double sampling operation on a specific noise level and a signal level of the electrical signal to output a difference level corresponding to a difference between the noise level and the signal level.

The analog-to-digital converter 7 may convert analog signals, corresponding to the difference level output from the correlated double sampler 6, into digital signals and may then output the converted digital signals.

The input/output buffer 8 may latch the digital signals, and the latched digital signals may be sequentially output to a video signal processor based on the decoded result from the column decoder 4.

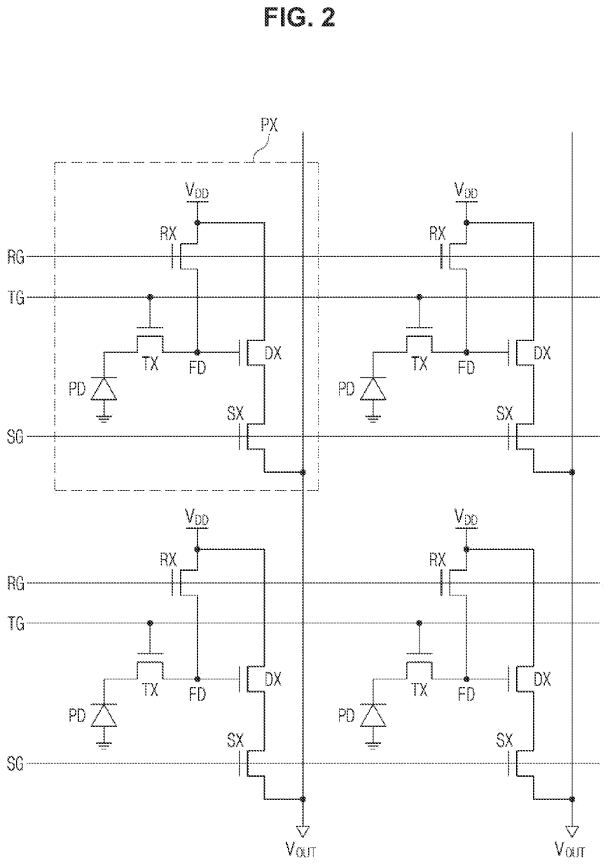

FIG. 2 is a circuit diagram of pixels in an image sensor according to an example embodiment.

Referring to FIG. 2, a pixel array may include a plurality of pixels, and the pixels may be arranged in a matrix form. Each of the pixels may include a transfer transistor TX and logic transistors RX, SX, and DX. The logic transistors may include a reset transistor RX, a select transistor SX, and a source follower transistor DX. The transfer transistor TX may have a transfer gate TG. Each of the pixels may further include a photoelectric conversion element PD and a floating diffusion region FD.

The photoelectric conversion element PD may generate and accumulate photocharges in proportion to the amount of externally incident light. The photoelectric conversion element PD may include a photodiode, a phototransistor, a photogate, a pinned photodiode, or combinations thereof. The transfer transistor TX may transfer the charges, generated by the photoelectric conversion element PD, to the floating diffusion region FD. The floating diffusion region FD may receive the charges generated by the photoelectric conversion element PD and may cumulatively store the received charges.

The source follower transistor DX may be controlled depending on the amount of photocharges accumulated in the floating diffusion region FD.

The reset transistor RX may periodically reset the charges accumulated in the floating diffusion region FD. The reset transistor RX may include a drain electrode, connected to the floating diffusion region FD, and a source electrode connected to a power supply voltage VDD. When the reset transistor RX is turned on, the power supply voltage VDD connected to the source electrode of the reset transistor RX may be applied to the floating diffusion region FD. Accordingly, when the reset transistor RX is turned on, the charges accumulated in the floating diffusion region FD may be discharged to reset the floating diffusion region FD.

The source follower transistor DX may serve as a source follower buffer amplifier. The source follower transistor DX may amplify a potential change in the floating diffusion region FD and output the amplified potential change to an output line VOUT.

The select transistor SX may select pixels to be read in units of rows. When the select transistor SX is turned on, the power supply voltage VDD may be applied to the drain electrode of the source follower transistor DX.

Although FIG. 2 illustrates a unit pixel including one photoelectric conversion region and four transistors TX, RX, DX, and SX, the image sensor according to example embodiments is not limited thereto. For example, the reset transistor RX, the drive transistor DX, or the selection transistor SX may be shared by adjacent pixels. Accordingly, the degree of integration of the image sensor may be increased.

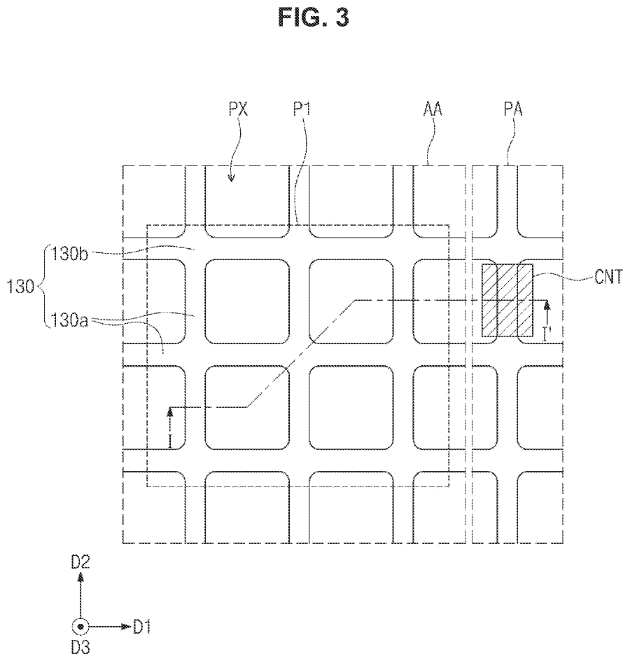

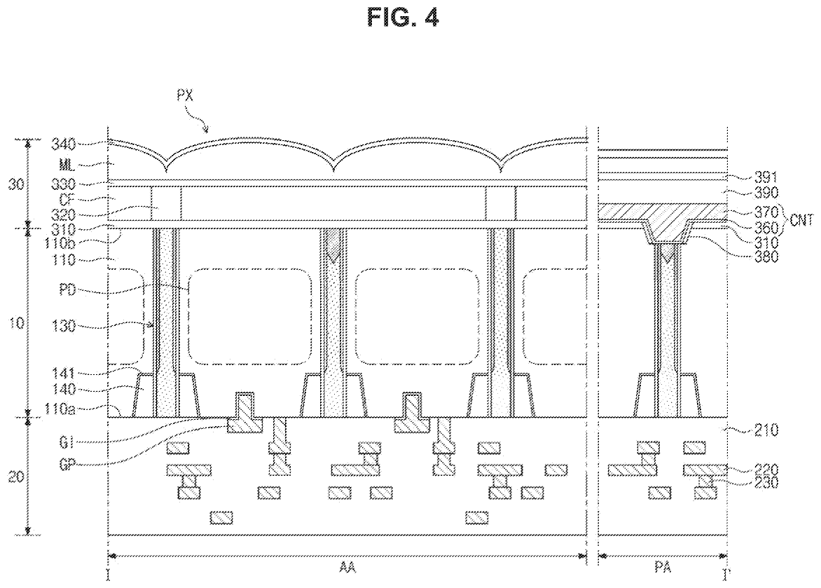

FIG. 3 is a plan view of an image sensor according to example embodiments, and FIG. 4 is a cross-sectional view corresponding to line I-I′ of FIG. 3.

Referring to FIGS. 3 and 4, the image sensor may include a photoelectric conversion layer 10, a circuit interconnection layer 20, and a light transmission layer 30. The photoelectric conversion layer 10 may be disposed between the circuit interconnection layer 20 and the light transmission layer 30.

The photoelectric conversion layer 10 may include a semiconductor substrate 110 having a first surface 110a and a second surface 110b opposing each other, a device isolation layer 130 penetrating through the semiconductor substrate 110, and a photoelectric conversion region PD provided within the semiconductor substrate 110 (the photoelectric conversion region is a region corresponding to the photoelectric conversion element and is represented by the same symbol PD as the photoelectric conversion element.)

The semiconductor substrate 110 may include an active region AA and a peripheral circuit region PA provided adjacent to the active region AA. The peripheral circuit region PA may be provided on at least one side of the active region AA, or may surround the active region AA when viewed in plan view.

The active region AA of the semiconductor substrate 110 is a region provided with a pixel array in which a plurality of pixels PX is arranged. The semiconductor substrate 110 may be a silicon substrate, a germanium substrate, a silicon-germanium substrate, a II-VI compound semiconductor substrate 110 or a III-V compound semiconductor substrate 110, or a silicon-on-insulator (SOI) substrate. The semiconductor substrate 110 may include a first conductivity type impurity, and thus the semiconductor substrate 110 may have a first conductivity type. The first conductivity type impurity may be a Group III element. For example, the first conductivity type impurity may include a P-type impurity such as aluminum (Al), boron (B), indium (In), and/or gallium (Ga).

The plurality of pixels PX may be arranged in a matrix on the semiconductor substrate 110 in a first direction D1 and a second direction D2 parallel to the first surface 110a of the semiconductor substrate 110. The first direction D1 and the second direction D2 may intersect each other (for example, orthogonally).

The device isolation layer 130 may penetrate through the semiconductor substrate 110, and may be disposed between pixels PX. The pixels PX may be defined by the device isolation layer 130. The device isolation layer 130 may penetrate through the semiconductor substrate 110 in a third direction D3 perpendicular to the first surface 110a. For example, the device isolation layer 130 may extend from the first surface 110a toward the second surface 110b. The first surface 110a may expose a lower surface of the device isolation layer 130, and may be substantially coplanar with the lower surface of the device isolation layer 130. The second surface 110b may expose an upper surface of the device isolation layer 130, and may be substantially coplanar with the upper surface of the device isolation layer 130.

The device isolation layer 130 includes side portions 130a, extending in a row direction and a column direction, and intersection portions 130b provided in a region in which the side portions 130a intersect each other. The side portion 130a may correspond to the opposing sides of two adjacent pixels PX, and the intersection portion 130b may correspond to the opposing corners of the four adjacent pixels PX.

The photoelectric conversion region PD may be disposed within each of the pixels PX. The photoelectric conversion regions PD may be interposed between the first surface 110a and the second surface 110b of the semiconductor substrate 110. The photoelectric conversion regions PD may be doped regions containing impurities of a second conductivity type, opposite to impurities of a first conductivity type. In an example embodiment, the photoelectric conversion regions PD may include a Group V element as an impurity, and the Group V element may be a second conductivity type impurity. The second conductivity type impurity may include an N-type impurity such as phosphorus, arsenic, bismuth, and/or antimony. The photoelectric conversion region PD may constitute a photodiode by forming a PN junction with the semiconductor substrate 110.

A shallow separation layer 140 may be provided within each pixel PX. The shallow separation layer 140 may be disposed adjacent to the first surface 110a and may be buried in the semiconductor substrate 110 on the first surface 110a. A pad layer 141 may be provided between the shallow separation layer 140 and the semiconductor substrate 110. An upper surface of the shallow separation layer 140 may be exposed by the first surface 110a. The shallow separation layer 140 may be formed of various insulating materials, and may include at least one of, for example, a silicon oxide, a silicon nitride, or a silicon oxynitride.

The circuit interconnection layer 20 may be provided on the first surface 110a of the semiconductor substrate 110. The circuit interconnection layer 20 may include a circuit portion, including a gate pattern GP and a gate insulating layer GI, and contact vias 230 and conductive lines 220 connected to the circuit portion. The contact vias 230 and conductive lines 220 may be provided on the interlayer dielectric 210 stacked on the first surface 110a. The interlayer dielectric 210 may cover the first surface 110a, the upper surface of the device isolation layer 130, and the upper surface of the shallow isolation layer 140. The interlayer dielectric 210 may also cover transistors constituting the circuit portion. The conductive lines 220 may be electrically connected to transistors through the contact vias 230. The interlayer dielectric 210 may include an insulating material, and the contact vias 230 and the conductive lines 220 may include a conductive material.

The gate pattern GP may be disposed on the first surface 110a of the semiconductor substrate 110. The gate pattern GP may function as a gate electrode of a transfer transistor, a source follower transistor, a reset transistor, or a select transistor for driving an image sensor. For example, the gate pattern GP may include a transfer gate, a source follower gate, a reset gate, or a select gate. In the drawings, for the sake of clarity, a single gate pattern GP is illustrated as being disposed in each pixel (PX), but example embodiments are not limited thereto and a plurality of gate patterns GP may be disposed in each pixel PX. As illustrated, the gate pattern GP may have a buried gate structure, but example embodiments are not limited thereto. In some example embodiments, the gate pattern GP may have a planar gate structure. The gate pattern GP may include a metal material, a metal silicide material, polysilicon, or combinations thereof.

The gate insulating layer GI may be interposed between the gate pattern GP and the semiconductor substrate 110. The gate insulating layer GI may include, for example, a silicon-based insulating material (for example, a silicon oxide, a silicon nitride, and/or a silicon oxynitride) and/or a high-k dielectric material (for example, a hafnium oxide and/or an aluminum oxide).

The light transmission layer 30 may be disposed on the second surface 110b of the semiconductor substrate 110. The light transmission layer 30 may be a layer through which light, traveling from the outside to the photoelectric conversion region PD, passes and the second surface 110b of the semiconductor substrate 110 may serve as a light incident surface. The light transmission layer 30 may include color filters CF, a fence pattern 320, and microlenses ML disposed on the second surface 110b. The color filters CF may be disposed between the second surface 110b and the microlenses ML. The light transmission layer 30 may collect and filter light, incident from the outside, and provide the light to the photoelectric conversion layer 10.

The color filters CF may be provided on the semiconductor substrate 110 on which the photoelectric conversion elements PD and the device isolation layer 130 are formed. According to example embodiments, four pixels PX arranged in a 2×2 matrix may implement the same color. Alternatively, four pixels PX arranged in a 2×2 matrix may each implement a single color, among red, green, and blue colors. For example, four pixels PX arranged in a 2×2 matrix may respectively implement red, green, green, and blue colors.

The color filters CF may be disposed for each pixel PX on the second surface 110b of the semiconductor substrate 110. For example, the color filters CF may be provided at locations corresponding to the photoelectric conversion elements PD. Each of the color filters CF may be selected as one of a plurality of reference colors. A plurality of standard colors may include, for example, red-green-blue (RGB), red-green-blue-white (RGBW), cyan-magenta-yellow (CMY), cyan-magenta-yellow-black (CMYK), red-yellow-blue (RYB), and RGB IR ray (RGBIR). However, colors of the color filters CF are not limited thereto, and filters of other colors may be provided. The color filters CF may constitute color filter arrays.

The fence pattern 320 may be disposed on the device isolation layer 130. For example, the fence pattern 320 may vertically overlap the device isolation layer 130. The fence pattern 320 may have a planar shape corresponding to a shape of the device isolation layer 130. For example, when viewed in plan view, the fence pattern 320 may have a grid shape. When viewed in plan view, the fence pattern 320 may surround the color filters CF. At least a portion of the fence pattern 320 may be arranged to overlap the device isolation layer 130 vertically (for example, in a third direction D3).

The fence pattern 320 may be interposed between two adjacent color filters (CF). The plurality of color filters CF may be physically and optically separated from each other by the fence pattern 320. Accordingly, the fence pattern 320 may guide light such that the light incident on the second surface 110b is incident into the photoelectric conversion region PD.

The fence pattern 320 may include metal, but example embodiments are not limited thereto. The fence pattern 320 may also include a low-refractive material. The low-refractive material may include a polymer and silica nanoparticles in the polymer. The low-refractive materials may have insulating properties. For example, the fence pattern 320 may include metal and/or metal nitride. For example, the fence pattern 320 may include titanium and/or titanium nitride.

The microlenses ML may be disposed on the plurality of color filters CF. At least a portion of the microlenses ML may be disposed to overlap the photoelectric conversion regions PD vertically (for example, in the third direction D3). The microlenses ML are used to converge light incident on the semiconductor substrate 110 and may include a spherical lens, an aspherical lens, or a combination thereof. The microlenses ML may be provided at locations corresponding to the photoelectric conversion regions PD of the semiconductor substrate 110.

The microlens ML is transparent, allowing light to pass therethrough. The microlenses ML may include an organic material such as polymer. For example, the microlens ML may include a photoresist material or a thermosetting resin.

The color filters CF, the fence patterns 320, and/or the microlenses ML have been described as being provided at overlapping locations corresponding to respective pixels PX, but example embodiments are not limited thereto. At least one of the color filters CF, the fence patterns 320, and the microlenses ML may have an offset structure shifted from a location corresponding to each pixel PX by a predetermined degree. Such an offset structure may result from a process margin of the color filters CF, the fence patterns 320, and/or the microlenses ML, or may be intentionally selected to optimize an optical path in consideration of an angle of light traveling from the outside to the pixel PX, or the like.

A passivation layer 340 may be provided on the microlenses ML. The microlenses ML and the passivation layer 340 may extend to the peripheral circuit region PA in a planar shape on the second surface 110b.

The upper insulating layer 310 may be interposed between the second surface 110b of the semiconductor substrate 110 and the color filters CF and between the device isolation layer 130 and the fence pattern 320. The upper insulating layer 310 may cover the second surface 110b of the semiconductor substrate 110 and the upper surface of the device isolation layer 130. The upper insulating layer 310 may include a plurality of layers. For example, the upper insulating layer 310 may include an antireflective layer. The antireflective layer may be formed of various materials, for example, hafnium oxide (HfOx), zirconium oxide (ZrO2), titanium oxide (TiO₂), aluminum oxide (Al₂O₃, alumina), or the like. In this case, the upper insulating layer 310 may prevent light reflection such that light incident on the second surface 110b of the semiconductor substrate 110 may smoothly reach the photoelectric conversion region PD.

A contact portion CNT may be provided in the peripheral circuit region PA of the semiconductor substrate 110. The contact portion CNT may be disposed adjacent to the second surface 110b, and a portion of the contact portion CNT may be buried in the semiconductor substrate 110. The contact portion CNT may be in direct contact with the upper surface of a buried conductive pattern 137 and/or a conductive liner 135 to be described later.

The contact portion CNT may include a metal pattern 370, extending into the semiconductor substrate 110 on the upper insulating layer, and a barrier pattern 360 surrounding the metal pattern 370.

A contact insulating layer 380 may be provided on an external portion of the contact portion CNT to surround the contact portion CNT. The contact portion CNT may extend to another region and be electrically connected to a through-silicon via (TSV) or a back vias stack (BVS). Thus, a negative bias voltage may be applied to the buried conductive pattern 137 and/or the conductive liner 135 through the contact portion CNT. As a result, issues such as white spot or dark current may be prevented or reduced.

A bulk color filter 390 and a protective layer 391 may be sequentially provided on the contact portion CNT of the peripheral circuit region PA. The bulk color filter 390 may be interposed between the contact portion CNT and the microlenses ML, and the protective layer 391 may be interposed between the bulk color filter 390 and the microlenses ML.

Hereinafter, a device isolation layer according to an example embodiment will be described in detail with reference to accompanying drawings.

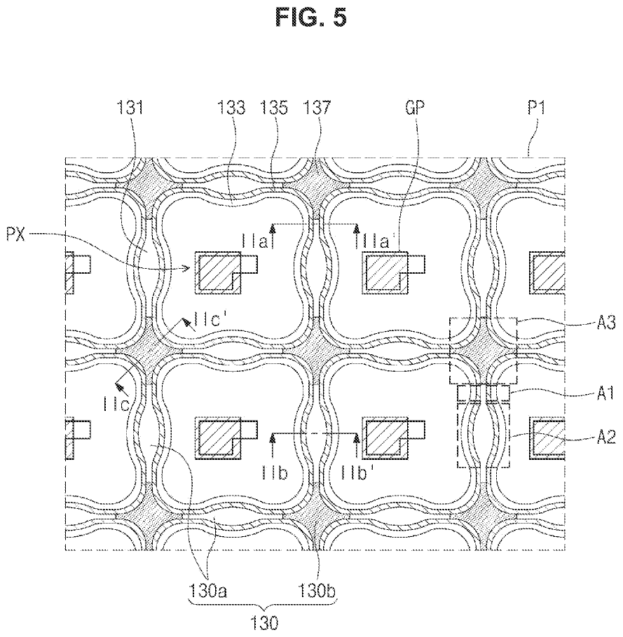

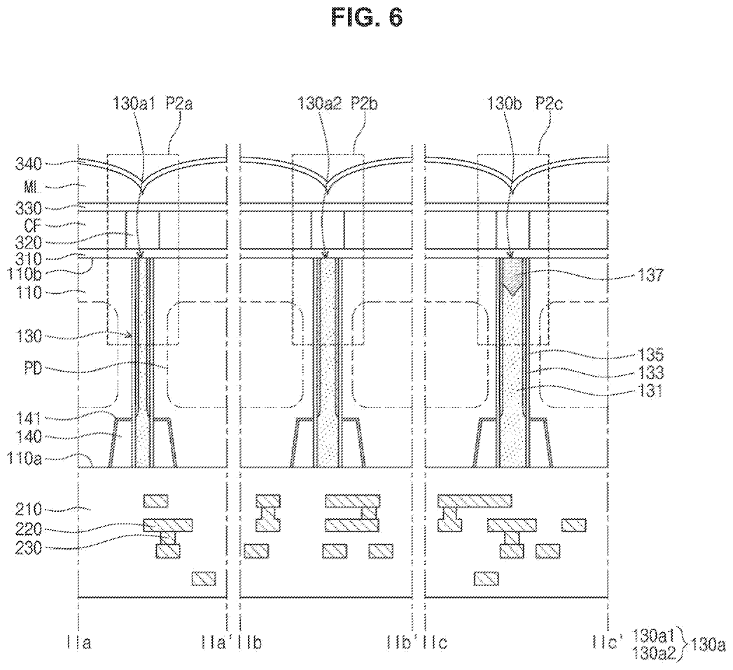

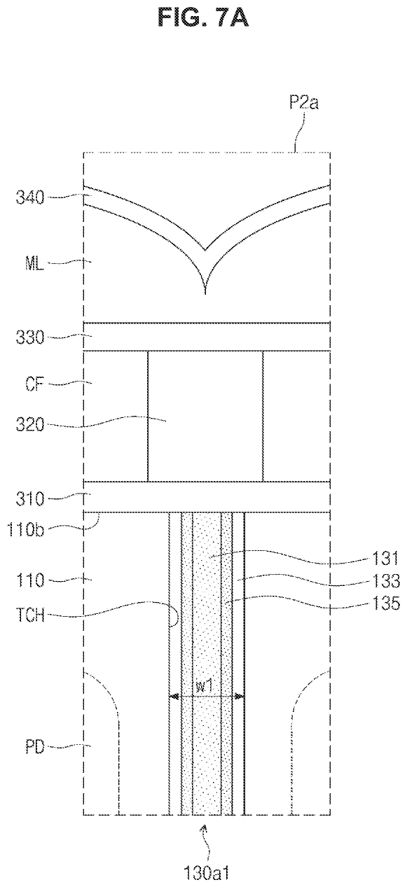

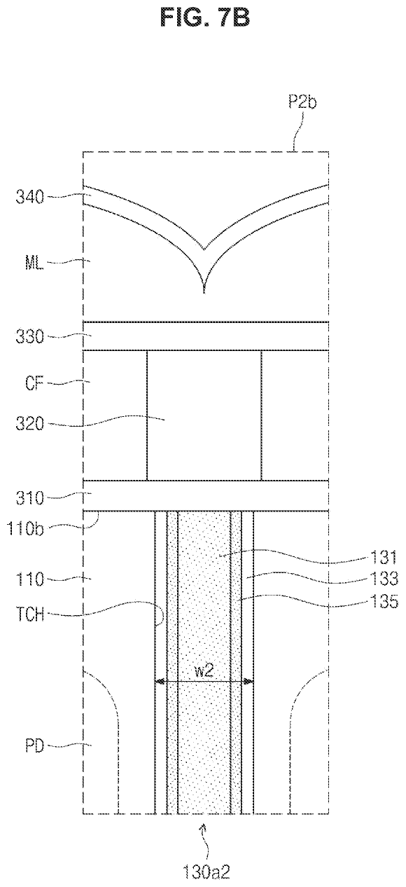

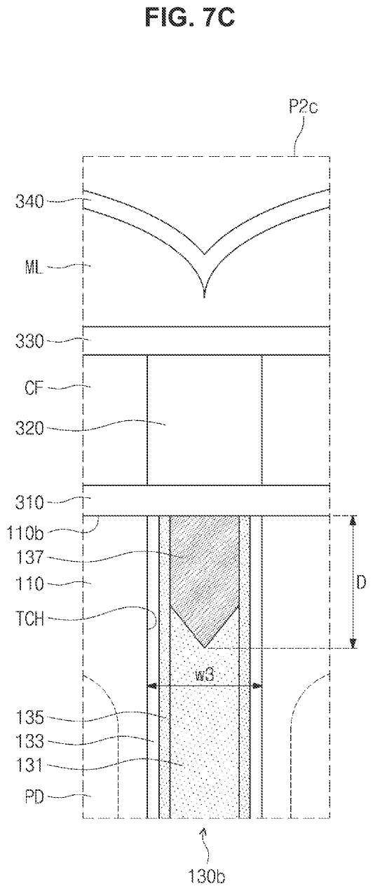

FIG. 5 is a plan view of an image sensor according to an example embodiment when viewed from above, and corresponds to P1 of FIG. 3. FIG. 6 includes cross-sectional views taken along lines IIa-IIa′, IIb-IIb′, and IIc-IIc′ of FIG. 5, and FIGS. 7A, 7B, and 7C are enlarged cross-sectional views of P2a, P2b, and P2c of FIG. 5, respectively. The following plan views of the image sensor, including FIG. 5, mainly illustrate a device isolation layer and a gate pattern among the components constituting the image sensor, and other components are omitted. The gate pattern is actually disposed on a lower side of the image sensor. However, the gate pattern may be illustrated when viewed from above, for the sake of clarity.

Referring to FIGS. 5, 6, and 7A to 7C, pixels PX may be arranged in a matrix when viewed in plan view, and the pixels PX may be separated by a device isolation layer 130.

The device isolation layer 130 may include side portions 130a, extending in a row direction and a column direction, and intersection portions 130b provided in a region in which the side portions 130a intersect each other.

The pixels PX may have different widths depending on an arrangement shape and locations thereof. For example, the device isolation layer 130 of the side portion 130a and the device isolation layer 130 of the intersection portion 130b may have the same width or different widths. Additionally, even in the side portion 130a, widths of the device isolation layer 130 at a portion close to the intersection portion 130b and a portion distant from the intersection portion 130b may be the same or different from each other. For example, in the side portion 130a, a region close to the intersection portion 130b may be referred to as a first region A1, a region distant from the intersection portion 130b may be referred to as a second region A2, and a region corresponding to the intersection portion 130b may be referred to as a third region A3. In this case, a width of the device isolation layer 130 in the second area A2 may be greater than a width of the device isolation layer 130 in the first area A1 and a width of the device isolation layer 130 in the third area A3 may be greater than the width of the device isolation layer 130 in the first region A1 and the second region A2.

In an example embodiment, for the sake of clarity, the device isolation layer in the first region A1 may be referred to as a first device isolation layer 130al, the device isolation layer in the second region A2 may be referred to as a second device isolation layer 130a2, and the device isolation layer in the third region A3 may be referred to as a third device isolation layer 130b, and widths of the first to third device isolation layers 130a1, 130a2, and 130b are referred to as first to third widths w1, w2, and w3, respectively. In this case, the first to third widths w1, w2, w3 may have sequentially larger values. The device isolation layer in the intersection portion may have the same configuration as the third device isolation layer and is therefore represented by the same symbol 130b.

In an example embodiment, the device isolation layer 130 may have not only a different width but also different shapes in different regions. The shapes of the device isolation layer 130 may be modified in various ways depending on the fabrication process. For example, at least a portion of the first to third device isolation layers 130a1, 130a2, and 130b may be formed to be different from the rest. In an example embodiment, the first device isolation layer 130a1 and the second device isolation layer 130a2 may be provided in substantially the same shape except that widths thereof are different from each other, and the third device isolation layer 130b may be provided in a shape, different from shapes of the first and second device isolation layers 130a1 and 130a2.

Hereinafter, the first and second device isolation layers 130a1 and 130a2 will be described in detail. Each of the first and second device isolation layers 130a1 and 130a2 may include a buried insulating pattern 131, a conductive liner 135, and an insulating liner 133 provided in the trench TCH penetrating through a first surface 110a and a second surface 110b of a semiconductor substrate 110.

The buried insulating pattern 131 may penetrate through the first surface 110a and the second surface 110b. For example, the buried insulating pattern 131 may extend from the first surface 110a to the second surface 110b. The buried insulating pattern 131 may fill the trench TCH from the first surface 110a to the second surface 110b. Accordingly, a lower surface of the buried insulating pattern 131 may be coplanar with the first surface 110a, and an upper surface of the buried insulating pattern 131 may be coplanar with the second surface 110b.

The buried insulating pattern 131 may be formed of an insulating material having improved gap-fill characteristics. For example, the buried insulating pattern 131 may include a boron-phosphor silicate glass (BPSG) layer, a high-density plasma (HDP) oxide layer, or a flowable chemical vapor deposition (FCVD) layer, ozone-tetraethyl orthosilicate (O₃-TEOS) layer, an undoped silicate glass (USG) layer, or tonen silazene (TOSZ) layer. However, the buried insulating pattern 131 is not limited thereto and may include, for example, an oxide layer containing a silicon oxide, a silicon nitride, and/or a silicon oxynitride.

In an example embodiment, the buried insulating pattern 131 may be selected from materials having a relatively low light absorption rate. For example, the buried insulating pattern 131 may include a material having a lower light absorption rate than doped or undoped silicon.

The conductive liner 135 may be interposed between the semiconductor substrate 110 and the buried insulating pattern 131. The conductive liner 135 may surround a periphery of each pixel PX when viewed in plan view. The conductive liners 135 surrounding adjacent pixels PX may be physically spaced apart from each other and may not be in contact with each other.

The conductive liner 135 may penetrate through the second surface 110b and the first surface 110a when viewed in cross section. For example, the conductive liner 135 may extend from the second surface 110b toward the first surface 110a when viewed in cross section, and the upper surface of the conductive liner 135 may be coplanar with the second surface 110b. The conductive liner 135 may be provided to have a predetermined length in a direction from the second surface 110b to the first surface 110a, and the predetermined length may be a distance between the first surface 110a and the second surface 110b, for example, may be smaller than or equal to a thickness of the semiconductor substrate 110. In an example embodiment, the length of the conductive liner 135 may be smaller than the distance between the first surface 110a and the second surface 110b, as illustrated. In an example embodiment, the length of the conductive liner 135 may be the same as the distance between the first surface 110a and the second surface 110b.

The conductive liner 135 may include a conductive material, for example, doped silicon, metal, or metal oxide. The doped silicon may be polysilicon doped with a first conductivity type impurity or a second conductivity type impurity. When the conductive liner 135 includes metal, tungsten, aluminum, or the like, may be used. The material for the conductive liner 135 is not limited thereto, and may include other conductive materials, such as various other metals and conductive materials containing the same, or doped inorganic materials.

The conductive liner 135 may serve to stably collect holes near the interface of the conductive liner 135 in a region adjacent to the device isolation layer 130 by applying a negative bias voltage through the buried conductive pattern 137 to be described later.

The insulating liner 133 may be interposed between the conductive liner 135 and the semiconductor substrate 110 to electrically insulate the semiconductor substrate 110 and the conductive liner 135. The insulating liner 133 may surround the periphery of each pixel PX when viewed in plan view, and may be disposed inside the conductive liner 135. The insulating liner 133 may penetrate through the first surface 110a and the second surface 110b. For example, the insulating liner 133 may extend from the first surface 110a to the second surface 110b, and lower and upper surfaces of the insulating liner 133 may be coplanar with the first surface 110a and the second surface 110b, respectively.

The insulating liner 133 may be provided along a sidewall of the trench TCH. The insulating liner 133 may cover both the second surface 110b of the semiconductor substrate 110 and the sidewall of the trench TCH penetrating through the second surface 110b.

The insulating liner 133 may include an insulating material such as a silicon-based insulating material (for example., silicon nitride (Si₃N₄), silicon oxide (SiO₂, silicate), silicon carbonitride (SiCN), silicon oxycarbonitride (SiOCN), or the like), or a high-κ metal oxide (for example, hafnium oxide (HfOx), zirconium oxide (ZrO₂), titanium oxide (TiO₂), aluminum oxide (Al₂O₃, alumina), or the like). The insulating liner 133 may be formed of a material having a lower refractive index than the first semiconductor substrate 110.

In an example embodiment, as illustrated, the insulating liner 133 may be formed as a single layer, but the insulating liner 133 is not limited thereto. As another example, the insulating liner 133 may include a plurality of layers, and the plurality of layers may include different materials. For example, the insulating liner 133 may be a composite layer formed of silicon oxide and silicon nitride (for example, SiN, SiCN, SiOCN, or the like).

Next, the third device isolation layer 130b is now described. The third device isolation layer 130b has a shape similar to a shape of each of the first and second device isolation layers 130a1 and 130a2, but is different from the first and second device isolation layers 130a1 and 130a2 in that the buried conductive pattern 137 is provided in a portion close to the second surface 110b. For example, the third device isolation layer 130b may include a buried insulating pattern 131 and a conductive liner 135, an insulating liner 133, and a buried conductive pattern 137, which are provided within a trench TCH penetrating through the first surface 110a and the second surface 110b of the semiconductor substrate 110.

The buried insulation pattern 131 in the third device isolation layer 130b may extend from the first surface 110a to the second surface 110b, and may fill the trench TCH except for a portion adjacent to the second surface 110b. For example, a portion of the buried insulation pattern 131 may be removed by a predetermined depth from the second surface 110b of the semiconductor substrate 110.

According to an example embodiment, an upper surface of the buried insulating pattern 131 may have a tapered shape, for example, a V-shape. For example, the upper surface of the buried insulating pattern 131 may be disposed to be further away from the second surface 110b at a central portion than at an edge. The shape of the upper surface of the buried insulating pattern 131 may result from a process of removing a portion of the buried insulating pattern 131, and may be different depending on process conditions. In an example embodiment, for the sake of clarity, the buried insulating pattern 131 is illustrated as having a non-planar upper surface. However, example embodiments are not limited thereto, and the buried insulating pattern 131 may be provided with a planar upper surface.

The conductive liner 135 may be formed of a material including doped polysilicon and metal. A dopant of the doped polysilicon may include a first conductivity type impurity or a second conductivity type impurity. For example, the conductive liner 135 may include boron-doped polysilicon. Alternatively, the conductive liner 135 may include polysilicon doped with phosphorus or arsenic. When boron or phosphorus is doped as an impurity, a concentration of the impurity may be about 5.0×10¹⁹ to about 5.0×10²²/cm³. In an example embodiment, the impurities doped in the conductive liner 135 may be diffused to the buried conductive pattern 137 by a heat treatment in a fabrication process. In this case, electrical conductivity of the buried conductive pattern 137 may be increased to improve efficiency of applying a negative bias to the device isolation layer 130. As a result, the sensitivity of the image sensor may be improved.

Similarly to the first and second device isolation layers 130a1 and 130a2, the insulating liner 133 may be interposed between the conductive liner 135 and the semiconductor substrate 110 to electrically insulate the semiconductor substrate 110 and the conductive liner 135. The insulating liner 133 may surround a periphery of each pixel PX but may be disposed inside the conductive liner 135 when viewed in plan view. The insulating liner 133 may penetrate through the first surface 110a and the second surface 110b, and an upper surface and a lower surface of the insulating liner 133 may be coplanar with the first surface 110a and the second surface 110b, respectively.

The insulating liner 133 may be provided along the sidewall of the trench TCH. The insulating liner 133 may cover the entire sidewall of the trench TCH penetrating through the second surface 110b of the semiconductor substrate 110.

The buried conductive pattern 137 may be provided in the trench TCH, in which the buried insulating pattern 131 is removed, to fill the trench TCH.

The buried conductive pattern 137 may be formed of a material including metal. Alternatively, the buried conductive pattern 137 may be formed of doped polysilicon. A dopant of the doped polysilicon may include a first conductivity type impurity or a second conductivity type impurity. For example, the buried conductive pattern 137 may include boron-doped polysilicon.

When the buried conductive pattern 137 includes metal, copper, tungsten, aluminum, or titanium may be used. However, example embodiments are not limited thereto, and other conductive materials such as various metals, doped inorganic materials, or combinations thereof may be used. Other conductive materials may include, for example, a conductive metal oxide, a metal grid, a random metal network, carbon nanotubes, graphene, nanowire meshes, an ultra-thin metal film, conductive polymer, or the like. In an example embodiment, the conductive metal oxide may include indium tin oxide (ITO), indium zinc oxide (IZO), aluminum-doped zinc oxide (ZnO: Al), indium gallium zinc oxide (IGZO), fluorine-doped tin oxide, and niobium-doped anatase. The buried conductive pattern 137 may be formed using thin film deposition, epitaxial growth, or impurity doping. For example, the conductive oxide such as indium tin oxide and the metal may be formed using physical/chemical deposition, and the doped silicon may be formed by deposition or epitaxial growth (boron, phosphorus, or arsenic doping).

The buried conductive pattern 137 may be provided to a point having a predetermined depth D from the second surface 110b. The trench TCH from the point having the predetermined depth D to the first surface 110a may be provided with a buried insulation pattern 131. A lower surface of the buried conductive pattern 137 may be in direct contact with an upper surface of the buried insulation pattern 131. In an example embodiment, a length of the buried conductive pattern 137 in a direction from the second surface 110b to the first surface 110a may be set in a variety of ways. For example, the length of the buried conductive pattern 137 in the direction from the second surface 110b to the first surface 110a may be about 1 nm to about 2000 nm. Alternatively, in an example embodiment, the length of the buried insulation pattern 131 in the direction from the first surface 110a to the second surface 110b may be greater than a length of the buried conductive pattern 137 in a direction from the second surface 110b to the first surface 110a. Alternatively, in an example embodiment, the length of the buried insulation pattern 131 may be at least 2 to 3 times greater than the length of the buried conductive pattern 137. However, the length of the buried conductive pattern 137 and the length of the buried insulation pattern 131 are not limited thereto.

In an example embodiment, the buried conductive pattern 137 may be provided only in a third region A3 in which a third device isolation layer 130b is disposed. A side surface of the buried conductive pattern 137 may be in direct contact with conductive liners 135 of adjacent pixels PX. Accordingly, the buried conductive patterns 137 may function as a bridge electrically connecting adjacent pixels PX to each other. As a result, the conductive liners 135 may be electrically connected through the buried conductive pattern 137 even when they are physically spaced apart from each other between two adjacent pixels PX, and when a negative bias voltage is applied to the buried conductive pattern 137, the negative bias voltage may also be applied to the conductive liner 135 as it is. Inversely, when a negative bias voltage is applied to the conductive liner 135, the negative bias voltage may also be applied to the buried conductive pattern 137.

According to an example embodiment, the buried conductive pattern 137 may be applied with a negative bias voltage by connecting an interconnection to the device isolation layer 130 through a contact portion CNT provided in the peripheral circuit region PA, as illustrated in FIG. 4. In an example embodiment, the contact portion CNT is connected to the buried contact pattern 137 to apply negative bias voltage. However, example embodiments are not limited thereto. For example, some components may be modified such that the contact portion CNT is applied to the conductive liner 135 to apply a negative bias voltage. In an example embodiment, an interconnection connected to the conductive liner 135 may be additionally provided within a circuit interconnection layer 20 on a lower surface of the device isolation layer 130.

In an example embodiment, for the sake of clarity, a side surface of the buried conductive pattern 137 and an internal side surface of the conductive liner 135 are illustrated as completely contacting each other, but example embodiments are not limited thereto. In an example embodiment, the side surface of the buried conductive pattern 137 may be in contact with only a portion of the internal side surface of the conductive liner 135.

In an example embodiment, a single buried conductive pattern 137 may be provided in the third device isolation layer 130b corresponding to the third region A3 and may be in direct contact with conductive liners 135 surrounding four adjacent pixels PX. Each of the conductive liners 135 provided in the four adjacent pixels PX may be in direct contact with another buried conductive pattern 137 at another corner of a pixel PX. In such a manner, the buried conductive patterns 137 may be in physical contact with the conductive liner 135 of each pixel PX to act as a bridge that electrically connects the buried conductive patterns 137 to the conductive liner 135. Accordingly, when a predetermined voltage is applied to one of the buried conductive patterns 137, the predetermined voltage may be applied to the conductive liners 135 of all of the device isolation layer 130 through the conductive liners 135 and the buried conductive patterns 137 that is in contact with the conductive liners 135. For example, when a negative bias is applied to one of the buried conductive patterns 137 or one of the conductive liners 135, a negative bias may be applied to all of the conductive liners 135 of the device isolation layer 130. The predetermined voltage may be applied through the contact portion CNT in the peripheral circuit region PA. As described above, the conductive liners 135 of each pixel PX may be applied with a negative bias voltage, serving to stably collect holes near the interface of the conductive liner 135 in a region adjacent to the device isolation layer 130.

In an example embodiment, the device isolation layer 130 may extend into the semiconductor substrate 110 through a shallow isolation layer 140. At least a portion of the buried insulation pattern 131 or the buried conductive pattern 137 of the device isolation layer 130 may be disposed within the shallow isolation layer 140. The insulating liner 133 of the device isolation layer 130 may extend between the shallow isolation layer 140 and the buried insulation pattern 131.

The image sensor having the above-described structure may significantly reduce a defect of dark current while significantly reducing loss of incident light, which is described as follows.

In an image sensor, one of the major causes of dark level is dark current. The dark current occurs due to the accumulation of electrons generated at an interface between the device isolation layer 130 and the photoelectric conversion region PD. To suppress a defect caused by the generation of dark current, the electrons generated at the interface between the device isolation layer 130 and the photoelectric conversion region PD should be captured to be prevented from moving to the photoelectric conversion region PD. To this end, according to the related arts, a conductive isolation layer was formed by filling a trench TCH with polysilicon, and dark current was prevented by applying a negative bias voltage to the conductive isolation layer.

However, when polysilicon fills a trench to be used as a conductive isolation layer, the polysilicon conductive isolation layer absorbs incident light. Polysilicon has a relatively higher light absorption rate than an insulating material such as silicon oxide or air, so that the polysilicon reduces the amount of light traveling to a photoelectric conversion region PD of an image sensor. As a result, sensitivity of the image sensor may be reduced.

In example embodiments, an absolute volume of the polysilicon used in the device isolation layer 130 is reduced while constantly maintaining application of a negative bias to a device isolation layer 130, and thus absorption of light traveling to each pixel PX may be significantly suppressed. To this end, polysilicon is not buried and a buried insulating pattern 131 is formed using a material having a lower light absorption rate than polysilicon to significantly reduce light absorption caused by polysilicon. Additionally, a thin conductive liner 135 is formed between the buried insulating pattern 131 and the insulating liner 133. The conductive liner 135 is provided between the insulating liner 133 and the buried insulating pattern 131, and has a significantly smaller thickness than existing polysilicon filling the trench TCH. As a result, even when a material having a high absorption rate such as polysilicon is used, the light absorption rate is significantly reduced compared to the existing polysilicon.

In addition, the conductive liner 135 is conductive, so that a negative bias voltage may be applied to the device isolation layer 130 through the conductive liner 135. This allows a dark current prevention effect by the existing polysilicon to be sufficiently obtained through the conductive liner 135.

Moreover, a buried conductive pattern 137 where light absorption may occur is formed in the intersection portion 130b, light traveling to the intersection portion 130b may be reflected to a side of the photoelectric conversion region PD. For example, when the buried conductive pattern 137 is formed of a metal material, the light traveling to the intersection portion 130b may be reflected due to the light reflection effect of the metal material, and an optical path may be changed to the inside of the pixel PX. Accordingly, the optical efficiency of the image sensor may be increased. The increase in optical efficiency of the image sensor indicates that the sensitivity of the image sensor is improved.

Even when the buried conductive pattern 137 is formed of polysilicon, the light traveling to the intersection portion 130b may travel to corners of adjacent pixels PX. Therefore, even when the light is absorbed by the buried conductive pattern 137, it does not have a substantial effect on the photoelectric conversion efficiency in the photoelectric conversion region PD. Rather, crosstalk caused by light traveling to another pixel PX through the corners of the adjacent pixels PX may be prevented.

As a result, a negative bias may be applied to the conductive liner 135 through the buried conductive pattern 137 to significantly reduce a light absorption rate due to the related polysilicon while preventing defects of the image sensor caused by the dark current. In addition, the buried insulation pattern 131 having high light transmittance may be used to significantly reduce loss of light incident on the photoelectric conversion region PD. Accordingly, the loss of light incident on the photoelectric conversion region PD may be significantly reduced to improve the photoelectric conversion efficiency and the sensitivity of the image sensor.

In the image sensor, the device isolation layer may be modified in a variety of ways without departing from example embodiments. In the following description, differences will be mainly described to avoid redundancy.

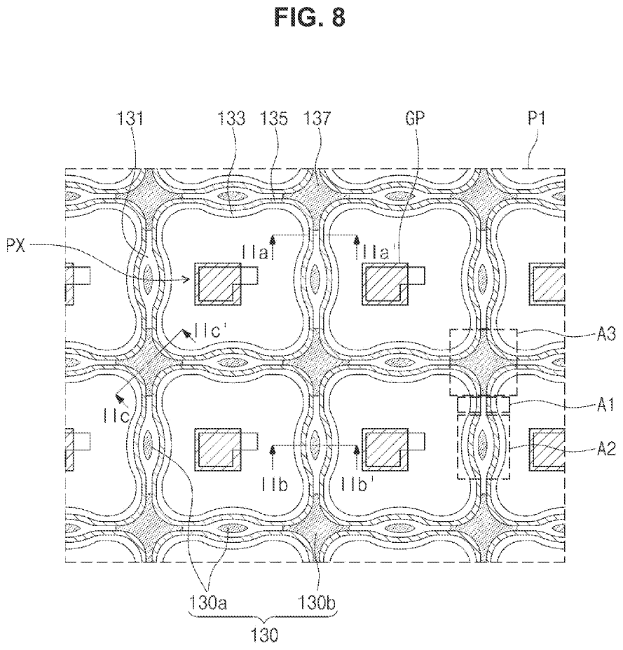

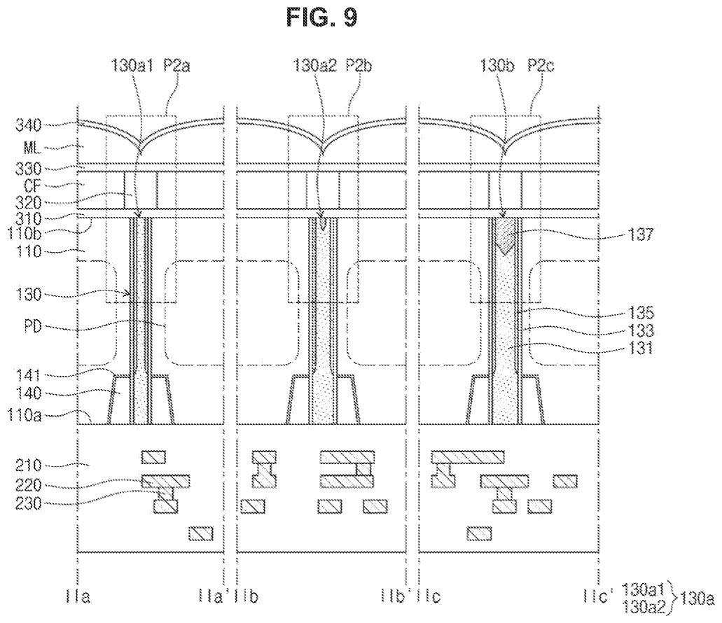

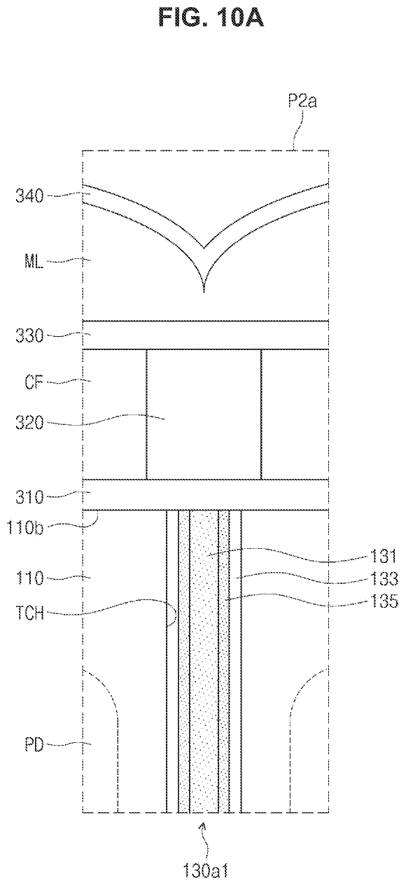

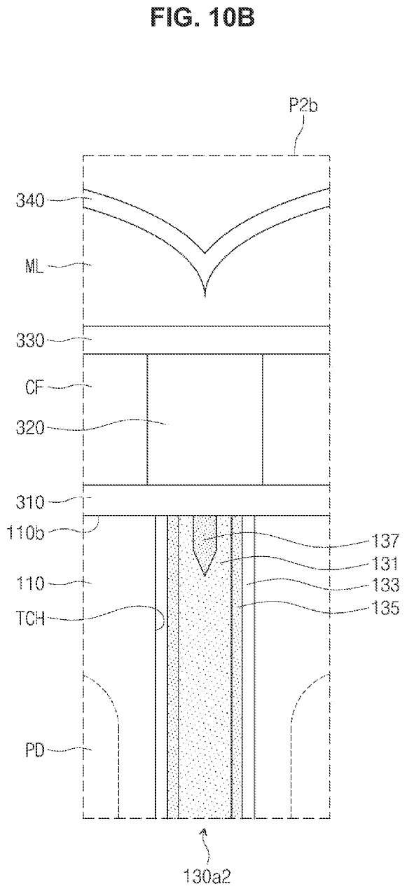

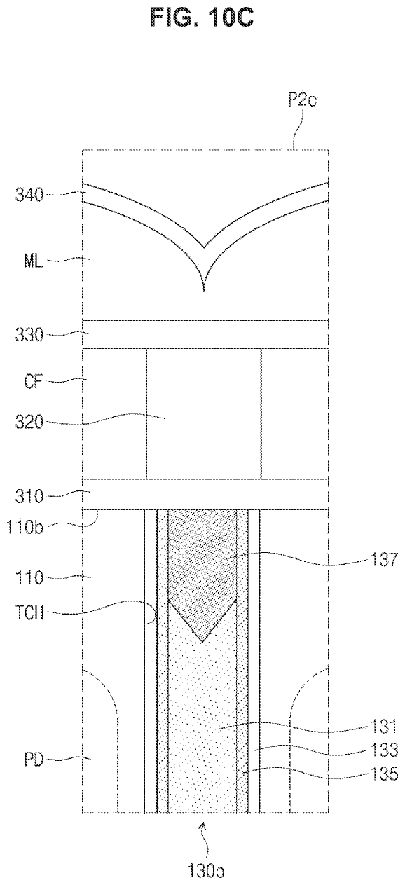

FIG. 8 is a plan view of the image sensor according to an example embodiment when viewed from above, and corresponds to P1 of FIG. 3. FIG. 9 is a cross-sectional view showing a cross section along lines IIa-IIa′, IIb-IIb′, and IIc-IIc′ of FIG. 8. FIGS. 10A, 10B, and 10C are enlarged cross-sectional views of P2a, P2b, and P2c of FIG. 9, respectively.

Referring to FIGS. 8, 9, and 10A to 10C, first to third device isolation layers 130a1, 130a2, and 130b may be provided in first to third regions A1, A2, and A3, respectively. The first to third device isolation layers 130a1, 130a2, and 130b may have the same width, but may have different widths as described above.

The first device isolation layer 130al, the second device isolation layer 130a2, and the third device isolation layer 130b may not only have different widths but also have different shapes.

The first device isolation layer 130a1 may include a buried insulating pattern 131, a conductive liner 135, and an insulating liner 133 provided within a trench TCH penetrating through a first surface 110a and a second surface 110b of a semiconductor substrate 110.

Each of the second device isolation layer 130a2 and the third device isolation layer 130b may include a buried insulating pattern 131, a conductive liner 135, an insulating liner 133, and a buried conductive pattern 137 provided within a trench TCH penetrating the first surface 110a and the second surface 110b of the semiconductor substrate 110.

The second device isolation layer 130a2 has a shape, similar to a shape of the third device isolation layer 130b, in that the buried conductive pattern 137 is provided in a portion close to a side of the second surface 110b of the semiconductor substrate 110. However, the second device isolation layer 130a2 has a different shape than the third device isolation layer 130b in terms of the shapes of the buried insulation pattern 131 and the buried conductive pattern 137.

In the second device isolation layer 130a2, the buried insulating pattern 131 may extend from the first surface 110a to the second surface 110b, and may fill the trench TCH but have a shape in which a portion of the buried insulating pattern 131 adjacent to the second surface 110b is removed. In this case, an upper surface of the buried insulating pattern 131 may be coplanar with the second surface 110b, and the removed portion may have a recess recessed from the upper surface. For example, the recess may correspond to the portion that is removed.

In the third device isolation layer 130b, the buried insulating pattern 131 may extend from the first surface 110a to the second surface 110b in a trench TCH, but may not fill the trench at a portion adjacent to the second surface 110b. For example, the buried insulating pattern 131 may, after being provided in the trench TCH, be removed to a predetermined depth from the second surface 110b of the semiconductor substrate 110.

The buried contact pattern 137 may be provided in (i.e., may fill) the removed portion in the buried insulating pattern 131, for example, the recess of the second device isolation layer 130a2 and a portion corresponding to a predetermined depth in the third device isolation layer 130b.

A side surface of the buried conductive pattern 137 disposed on the third device isolation layer 130b may be in direct contact with the conductive liner 135. The buried conductive pattern 137 disposed on the second device isolation layer 130a2, for example, the buried conductive pattern 137 filling the recess, may be spaced apart from the adjacent conductive liner 135. For example, the buried conductive pattern 137 on an upper end of the second device isolation layer 130a2 in the second region A2 may be provided in the form of an island from the conductive liner 135. Accordingly, the buried conductive pattern 137 and the second device isolation layer 130a2 may also be electrically insulated from each other.

A negative bias may be applied to the conductive liners 135 by a contact between the buried conductive pattern 137 and the conductive liners 135 in the third region A3. In the second region A2, the buried conductive pattern 137 and the conductive liners 135 may be provided with the island-shaped buried conductive pattern 137. Because the buried insulating pattern 131 extends between the buried conductive pattern 137 and the conductive liners 135, the buried conductive pattern 137 and the conductive liners 135 are not in contact with each other, and a voltage not be applied to the island-shaped buried conductive pattern 137.

The conductive liner 135 surrounding each pixel PX may be applied with a negative bias through the buried conductive pattern 137 provided in the third device isolation layer 130) of the third region A3, as described above.

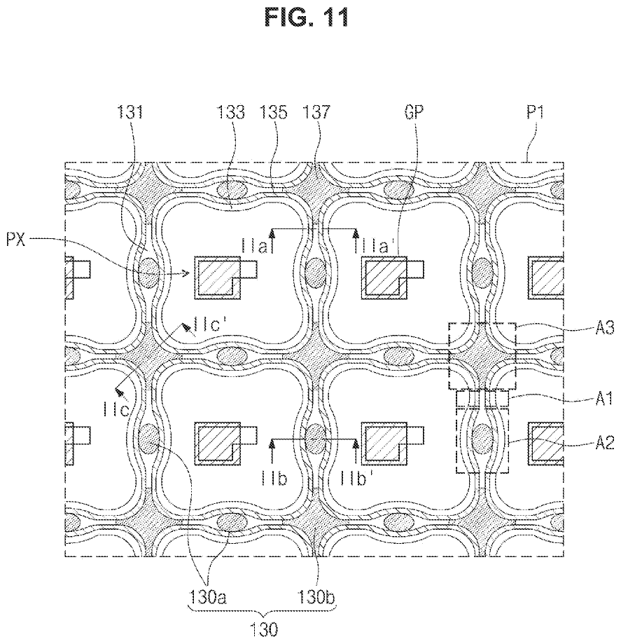

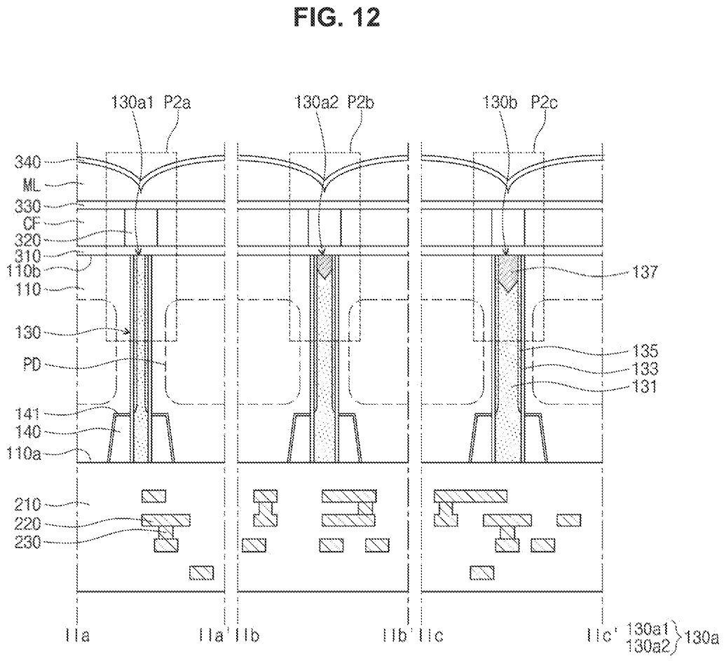

FIG. 11 is a plan view of an image sensor according to an example embodiment when viewed from above, and corresponds to P1 of FIG. 3. FIG. 12 includes cross-sectional views taken along lines IIa-IIa′, IIb-IIb′, and IIc-IIc′ of FIG. 11, and GS. 13A, 13B, and 13C are enlarged cross-sectional views of P2a, P2b, and P2c of FIG. 12, respectively.

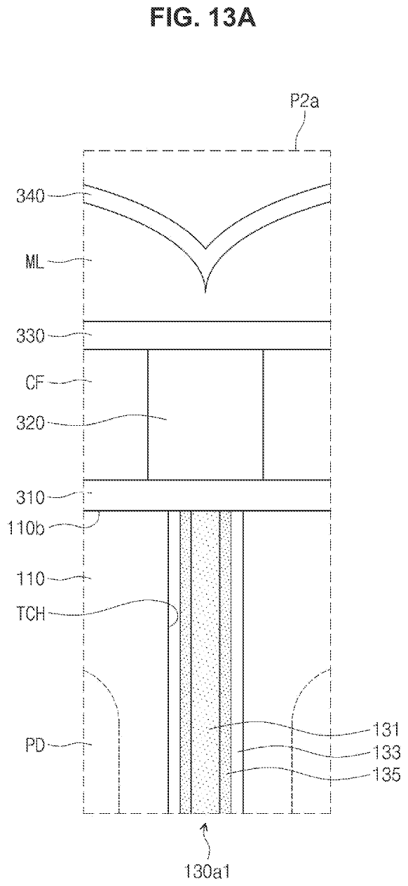

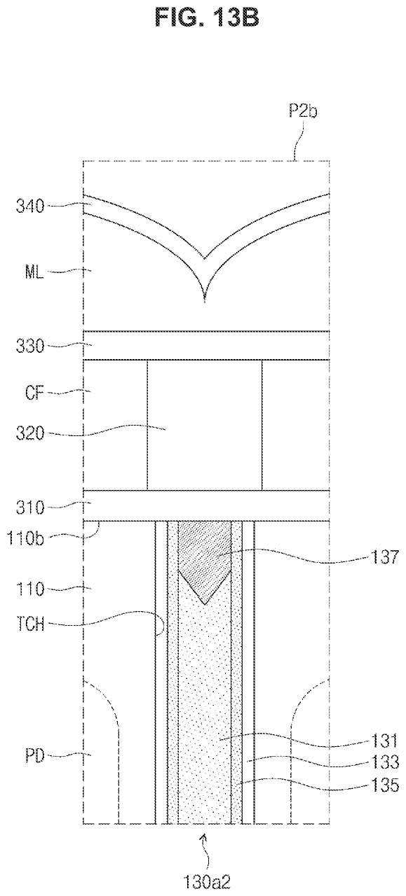

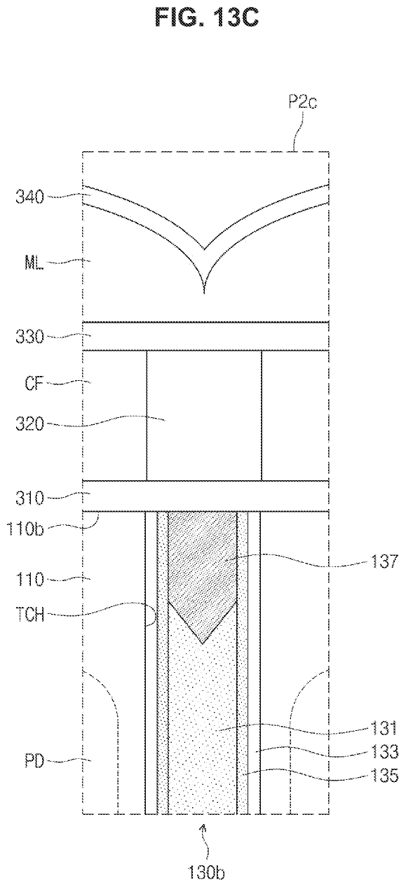

Referring to FIGS. 11, 12, and 13A to 13C, a first device isolation layer 130al, a second device isolation layer 130a2, and a third device isolation layer 130b may also be provided to have different widths and shapes.

The first device isolation layer 130a1 may include a buried insulating pattern 131, a conductive liner 135, and an insulating liner 133 provided within a trench TCH penetrating through a first surface 110a and a second surface 110b of a semiconductor substrate 110.

Each of the second device isolation layer 130a2 and the third device isolation layer 130b may include a buried insulating pattern 131, a conductive liner 135, an insulating liner 133, and a buried conductive pattern 137 provided in the trench TCH extending through the first surface 110a and the second surface 110b of the semiconductor substrate 110.

The second device isolation layer 130a2 has a shape, similar to a shape of the third device isolation layer 130b, in that the buried conductive pattern 137 is provided in a portion close to a side of the second surface 110b of the semiconductor substrate 110. However, the second device isolation layer 130a2 has a different shape than the third device isolation layer 130b in terms of the shapes of the buried insulation pattern 131 and the buried conductive pattern 137.

The second device isolation layer 130a2 has a shape, similar to a shape of the third device isolation layer 130b, in that the buried conductive pattern 137 is provided in a portion close to a side of the second surface 110b of the semiconductor substrate 110. However, the second device isolation layer 130a2 has a different shape than the third device isolation layer 130b in terms of the shapes of the buried insulation pattern 131 and the buried conductive pattern 137.

In the second device isolation layer 130a2, the buried insulating pattern 131 may extend from the first surface 110a to the second surface 110b, and be provided in the trench TCH but have a shape in which a portion of the buried insulating pattern 131 adjacent to the second surface 110b is removed. For example, after being provided in the trench TCH, the buried insulating pattern 131 may, after being provided in the trench TCH, be removed to a predetermined depth from the second surface 110b of the semiconductor substrate 110. For example, the recess may correspond to the portion that is removed.

In the third device isolation layer 130b, the buried insulating pattern 131 may extend from the first surface 110a to the second surface 110b in a trench TCH, but may not fill the trench at a portion adjacent to the second surface 110b. For example, the buried insulating pattern 131 may be removed to a predetermined depth from the second surface 110b of the semiconductor substrate 110.

In this case, there may be a difference in the depth at which the buried insulating pattern 131 is removed in the second device isolation layer 130a2 and the third device isolation layer 130b. For example, the depth at which the buried insulating pattern 131 is removed in the third device isolation layer 130b may be greater than the depth at which the buried insulating pattern 131 is removed in the second device isolation layer 130a2.

The buried conductive pattern 137 may be provided in a second region A2 and a third region A3, and may fill a portion of the trench TCH from which the buried insulation pattern 131 is removed. Accordingly, the buried conductive pattern 137 provided in the second device isolation layer 130a2 of the second region A2 may be in physical contact with a side surface of the conductive liner 135 of the second device isolation layer 130a2, and the buried conductive pattern 137 provided in the third device isolation layer 130b of the third region A3 may be in physical contact with a side surface of the conductive liner 135 of the third device isolation layer 130b. The contacts between the side surfaces of the buried conductive patterns 137 and the conductive liners 135 in the second and third device isolation layers 131a2 and 130b may be not only physical contacts, but also electrical contacts. Accordingly, the conductive liners 135 surrounding each pixel PX may be electrically connected not only by the buried conductive patterns 137 in the third region A3, but also by the buried conductive patterns 137 in the second region A2. As a result, a voltage may be uniformly applied to the entire pixel (PX) array.

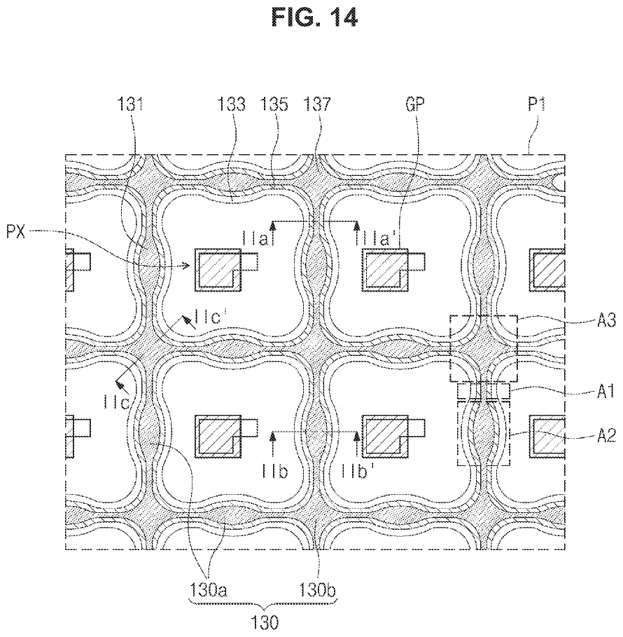

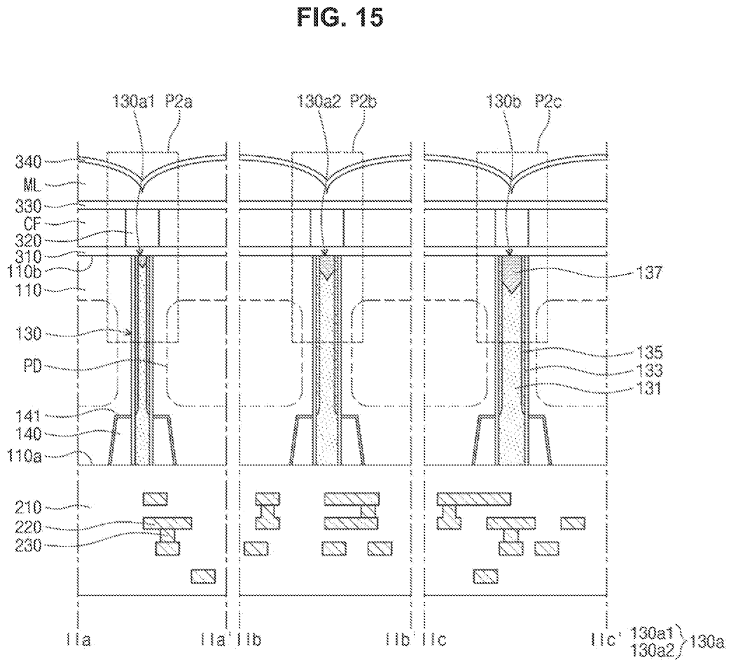

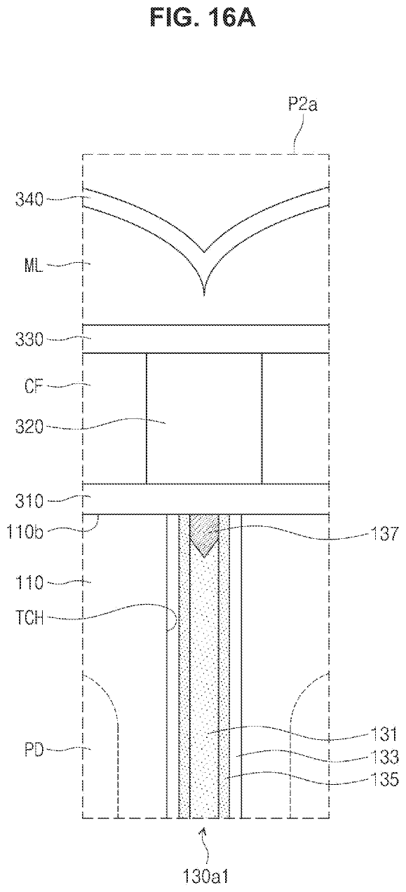

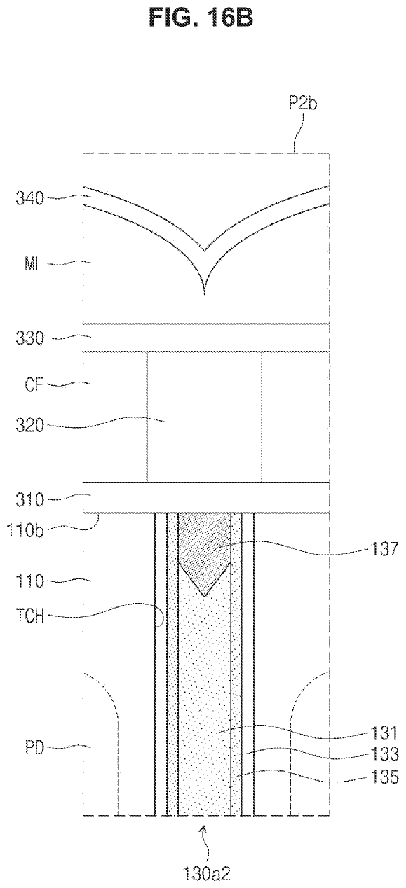

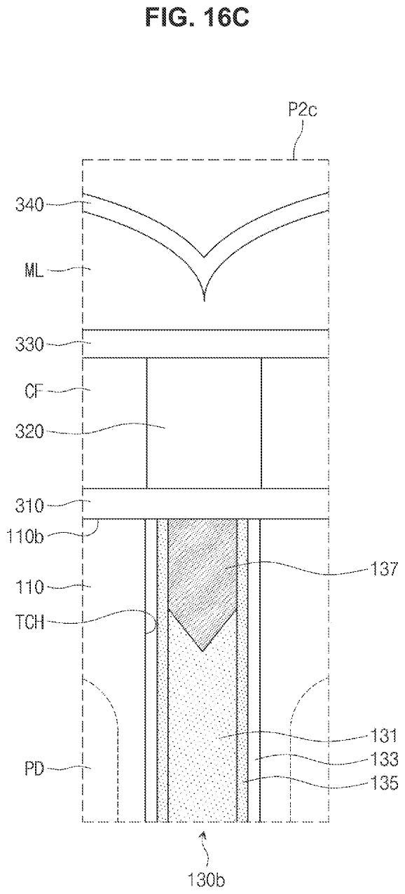

FIG. 14 is a plan view of an image sensor according to an example embodiment when viewed from above, and corresponds to P1 of FIG. 3. FIG. 15 includes cross-sectional views taken along lines IIa-IIa′, IIb-IIb′, and IIc-IIc′ of FIG. 14, and FIGS. 16A, 16B, and 16C are enlarged cross-sectional views of P2a, P2b, and P2c of FIG. 15, respectively.

Referring to FIGS. 14, 15, and 16A to 16C, a first device isolation layer 130al, a second device isolation layer 130a2, and a third device isolation layer 130b may have similar shapes.

Each of the first to third device isolation layers 130a1, 130a2, and 130b may include a buried insulating pattern 131, a conductive liner 135, an insulating liner 133, and a buried conductive pattern 137 provided within a trench TCH penetrating through a first surface 110a and a second surface 110b of a semiconductor substrate 110.

A buried conductive pattern 137 may be provided in all of the first to third device isolation layers 130a1, 130a2, and 130b in a portion close to the second surface 110b of the semiconductor substrate 110.

In the first to third device isolation layers 130a1, 130a2, and 130b, the buried insulating pattern 131 may extend from the first surface 110a to the second surface 110b, and may be provided in a trench TCH, but may not fill the trench at a portion adjacent to the second surface 110b. For example, after being provided in the trench TCH, the buried insulating pattern 131 may be removed to a predetermined depth from the second surface 110b of the semiconductor substrate 110.

In this case, there may be a difference in the depth at which the buried insulating pattern 131 is removed in the first to third device isolation layers 130a1, 130a2, and 130b. For example, the depth at which the buried insulating pattern 131 is removed in the first device isolation layer 130a1 may be greater than the depth at which the buried insulating pattern 131 is removed in the second device isolation layer 130a2, and the depth at which the buried insulating pattern 131 is removed in the second device isolation layer 130a2 may be greater than the depth at which the buried insulating pattern 131 is removed in the third device isolation layer 130b.

The buried conductive pattern 137 may be provided in all of the first to third device isolation layers 130a1, 130a2, and 130b, and may fill a portion of the trench TCH from which the buried insulation pattern 131 is removed. Accordingly, the buried conductive pattern 137 provided in the first device isolation layer 130a1 of the first region A1 may be in physical contact with a side surface of the conductive liner 135 of the first device isolation layer 130al, the buried conductive pattern 137 provided in the second device isolation layer 130a2 of the second region A2 may be in physical contact with a side surface of the conductive liner 135 of the second device isolation layer 130a2, and the buried conductive pattern 137 provided in the third device isolation layer 130b of the third region A3 may be in physical contact with a side surface of the conductive liner 135 of the third device isolation layer 130b. The contacts between the side surfaces of the buried conductive patterns 137 and the conductive liners 135 in the first to third device isolation layers 130a1, 130a2, and 130b may be not only physical contacts, but also electrical contacts. Accordingly, the conductive liners 135 surrounding each pixel PX may be electrically connected overall by the buried conductive patterns 137 of the first to third regions A1 to A3. As a result, a voltage may be more uniformly applied to the entire pixel (PX) array.

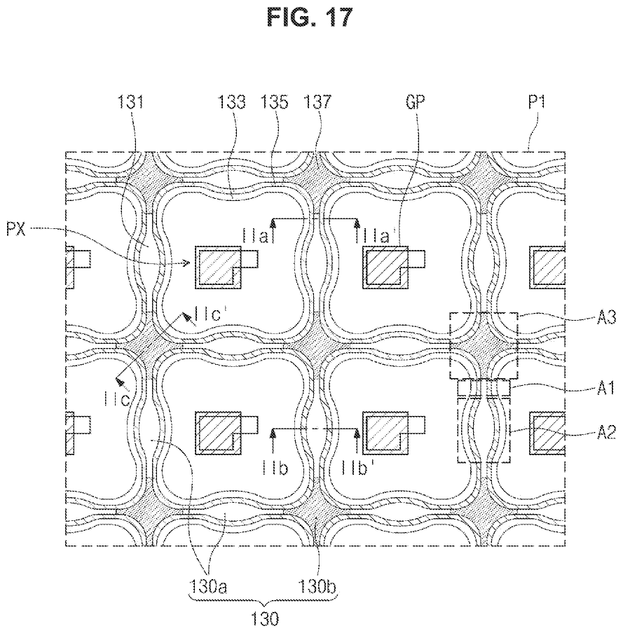

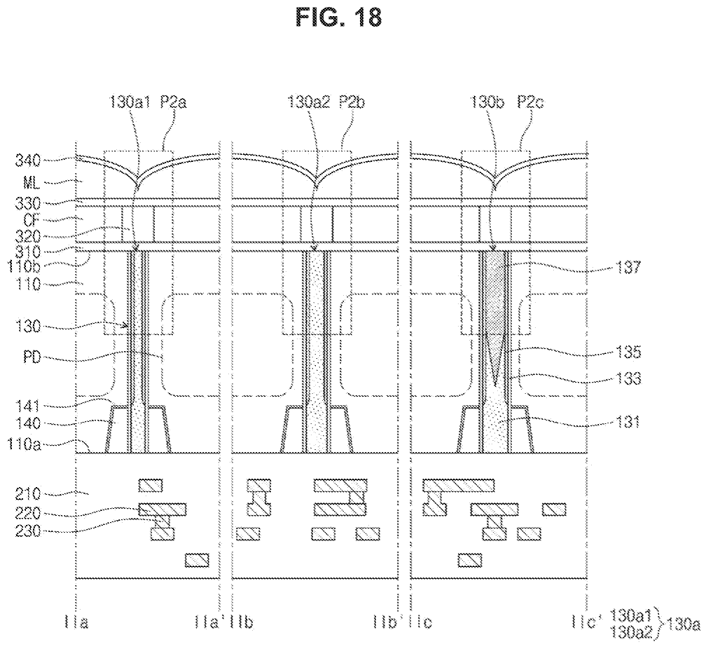

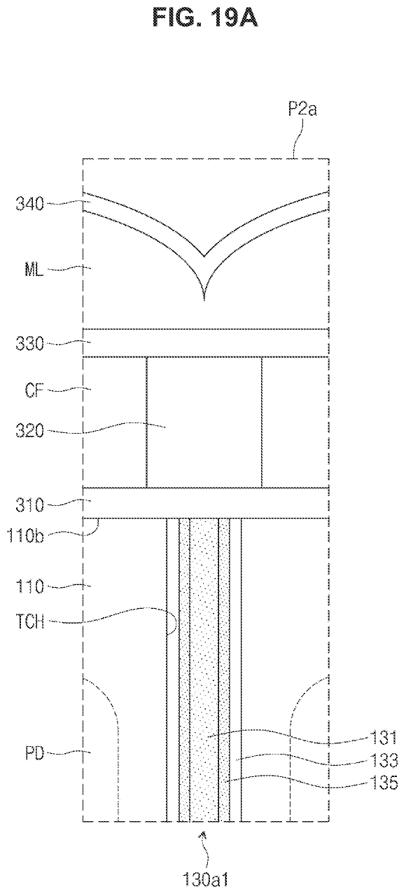

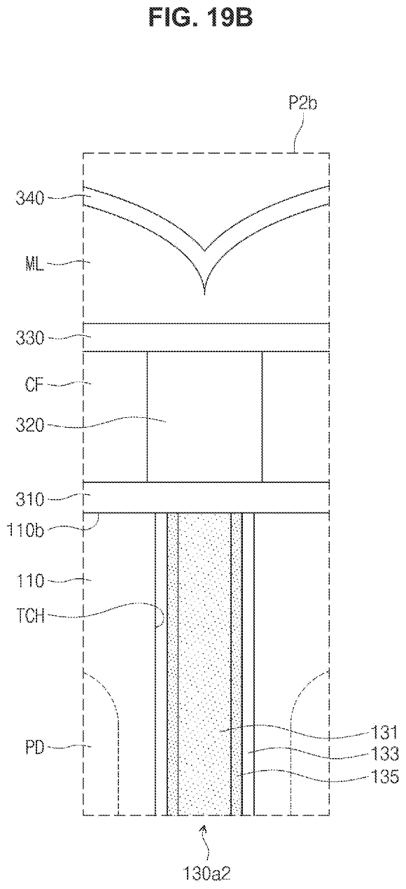

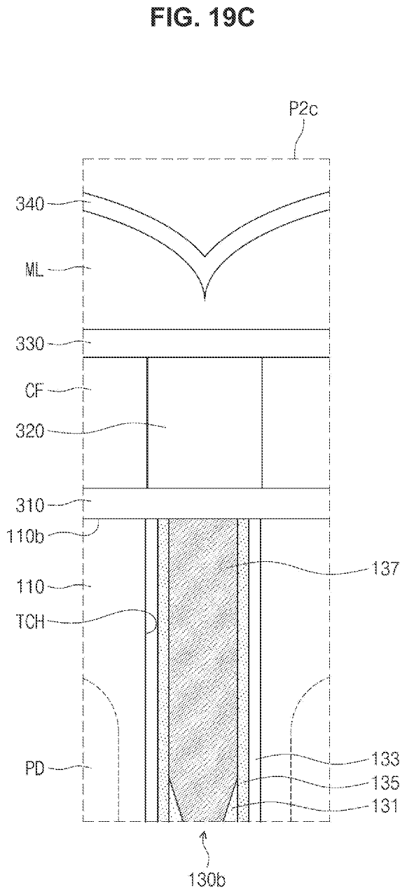

FIG. 17 is a plan view of an image sensor according to an example embodiment when viewed from above, and corresponds to P1 of FIG. 3. FIG. 18 includes cross-sectional views taken along lines IIa-IIa′, IIb-IIb′, and IIc-IIc′ of FIG. 17, and FIGS. 19A, 19B, and 19C are enlarged cross-sectional views of P2a, P2b, and P2c of FIG. 18, respectively.

Referring to FIGS. 17, 18, and 19A to 19C, in an example embodiment, a first device isolation layer 130a1 and a second device isolation layer 130a2 may be provided to have substantially the same shape except that they have different widths. A third device isolation layer 130b may be provided to have a shape, different from the shapes of the first and second device isolation layers 130a1 and 130a2, and a length of a buried conductive pattern 137 may be modified to be different from that described above.

In the third device isolation layer 130b, the buried insulating pattern 131 may extend from the first surface 110a to the second surface 110b, and may be provided in a trench TCH but may not fill the trench at a portion adjacent to the second surface 110b. For example, after being provided in the trench TCH, the buried insulating pattern 131 may be removed to a predetermined depth from the second surface 110b of the semiconductor substrate 110.

The buried conductive pattern 137 may be provided to a predetermined depth from the second surface 110b. The buried insulating pattern 131 may be provided within the trench TCH from a point at the predetermined depth to the first surface 110a. A lower surface of the buried conductive pattern 137 may be in direct contact with an upper surface of the buried insulating pattern 131. In an example embodiment, a length of the buried insulating pattern 131 in a direction from the first surface 110a to the second surface 110b may be less than or similar to a length of the buried conductive pattern 137 in a direction from the second surface 110b to the first surface 110a.

The buried conductive pattern 137 may be provided in a third region A3 in which the third device isolation layer 130b is disposed, and a side surface of the buried conductive pattern 137 may be in direct contact with the conductive liner 135. A length of the buried conductive pattern 137 in a direction from the second surface 110b to the first surface 110a may be larger than or similar to a length of the buried insulating pattern 131 in a direction from the first surface 110a to the second surface 110b. Therefore, a contact area between the side surface of the buried conductive pattern 137 and the conductive liner 135 may be much larger than in other example embodiments. As a result, the conductive liners 135 surrounding each pixel PX may stably and electrically contact the buried conductive patterns 137 in the third region A3, and a voltage may be stably and uniformly applied to the entire pixel array PX.

As described above, a device isolation layer may be modified in various ways without departing from example embodiments.

Image sensors having the above-described structures may be fabricated by the following process, which will be described below with reference to accompanying drawings.

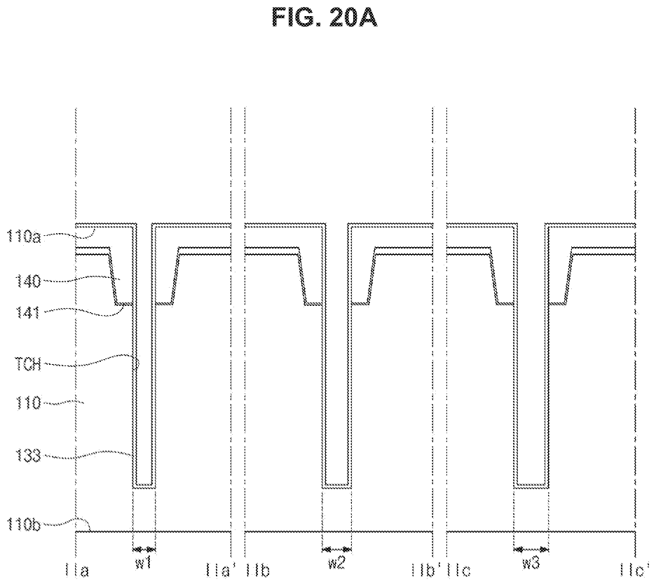

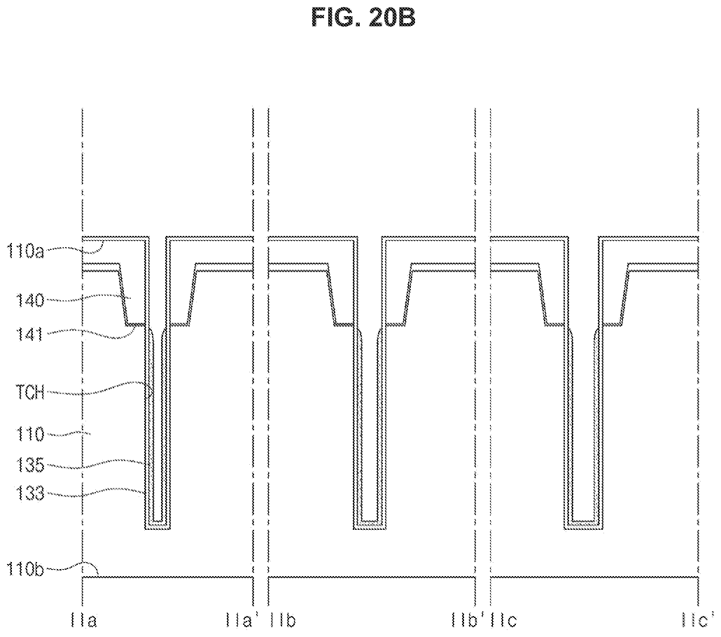

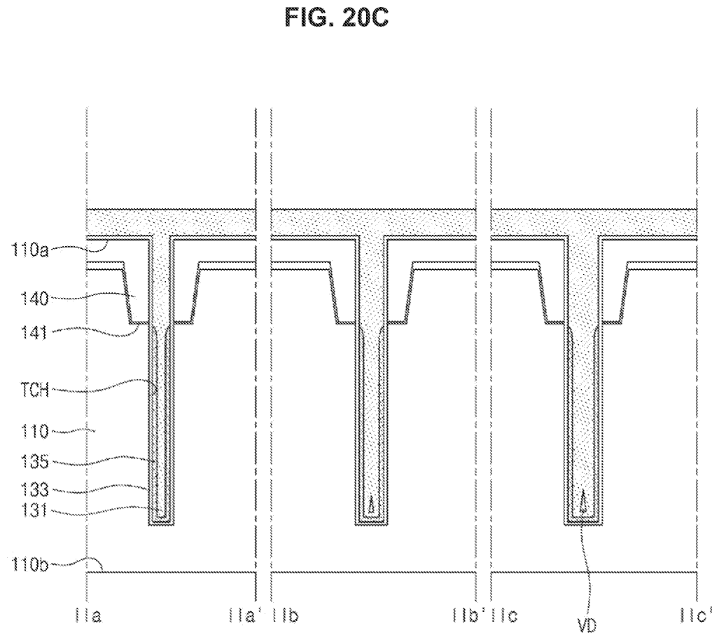

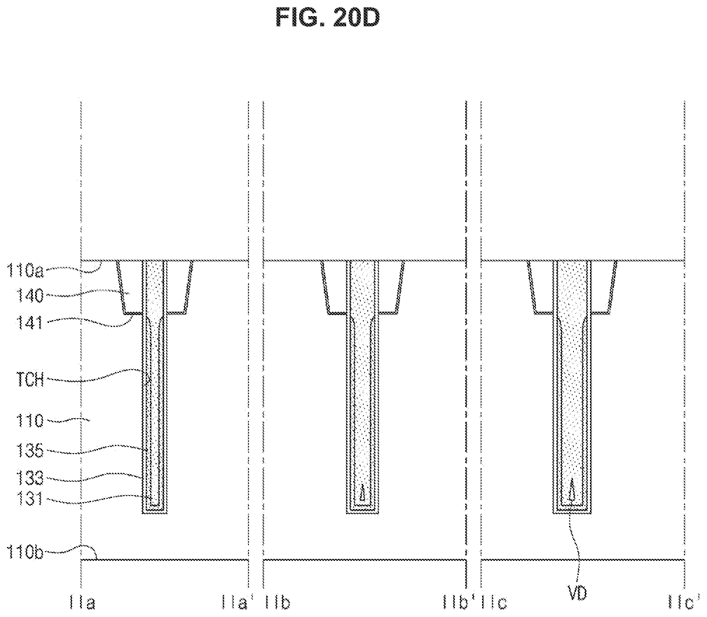

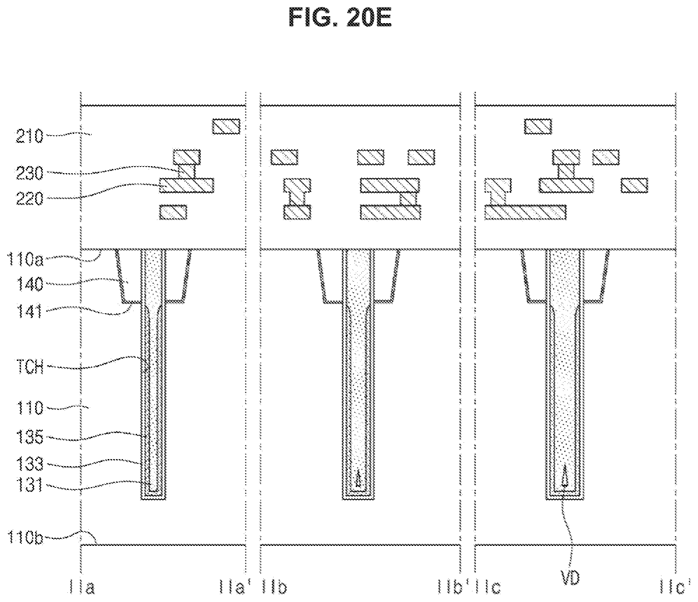

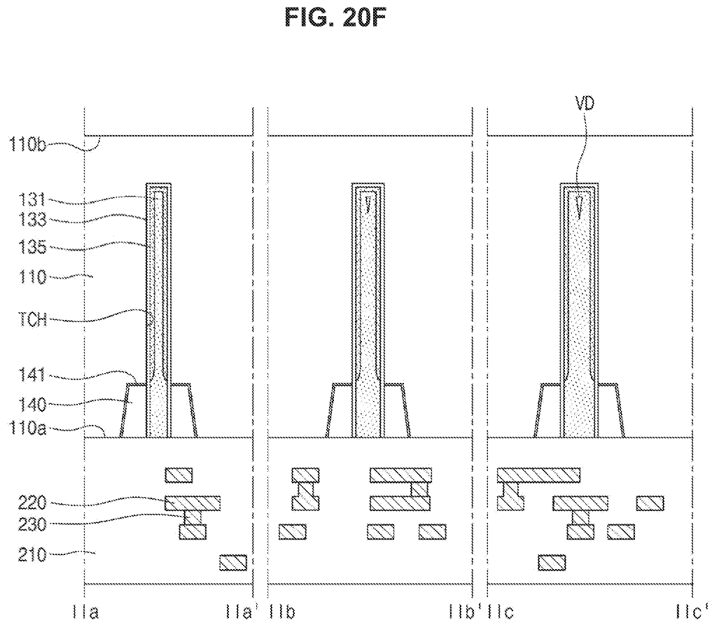

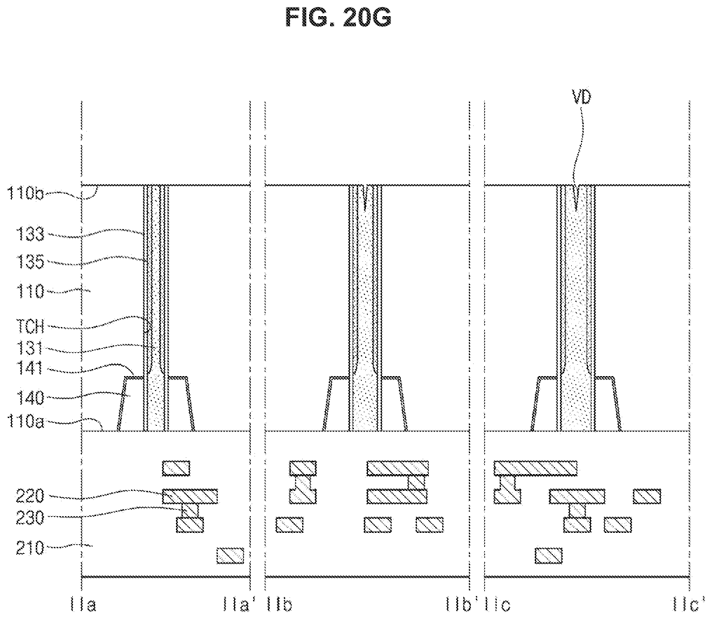

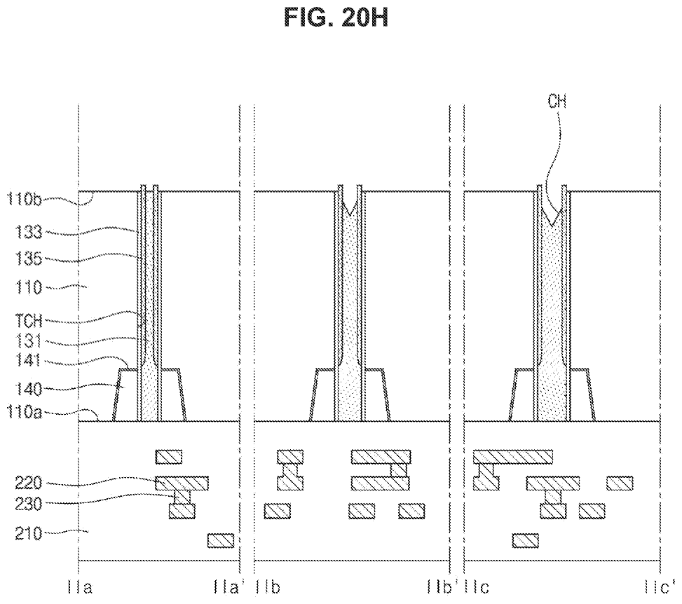

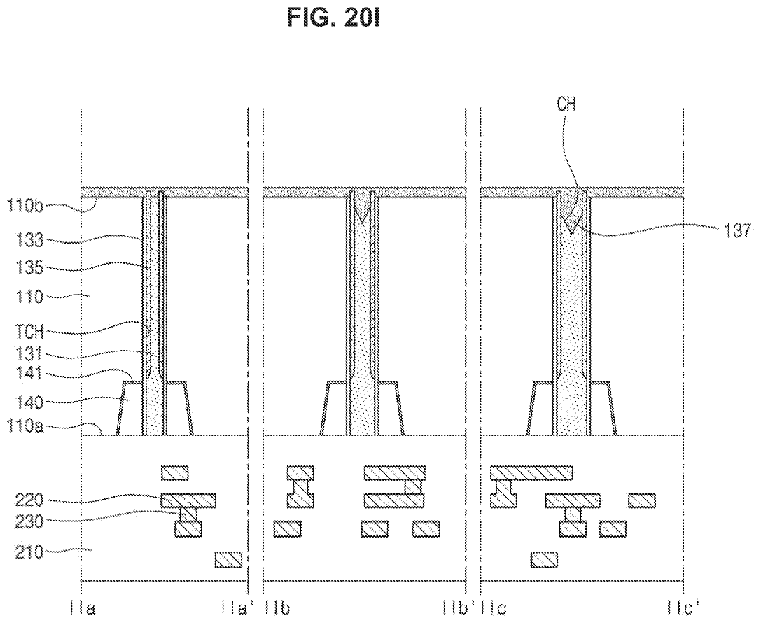

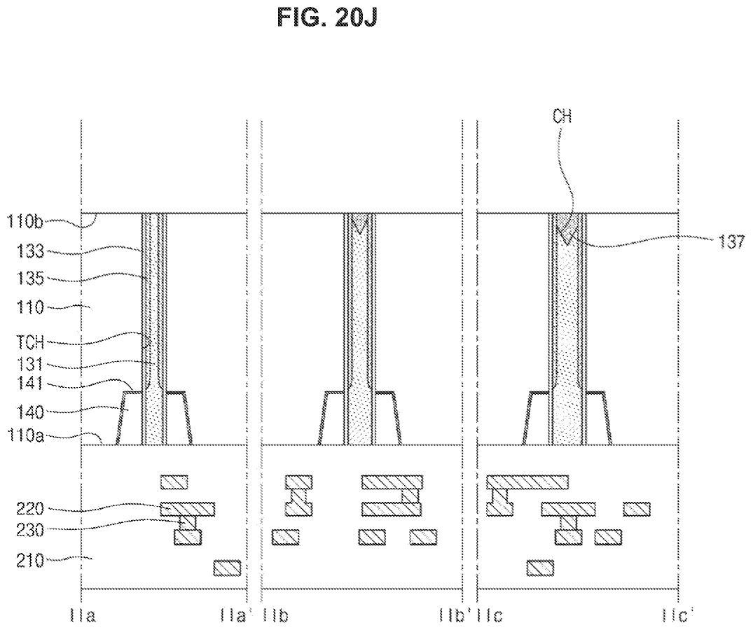

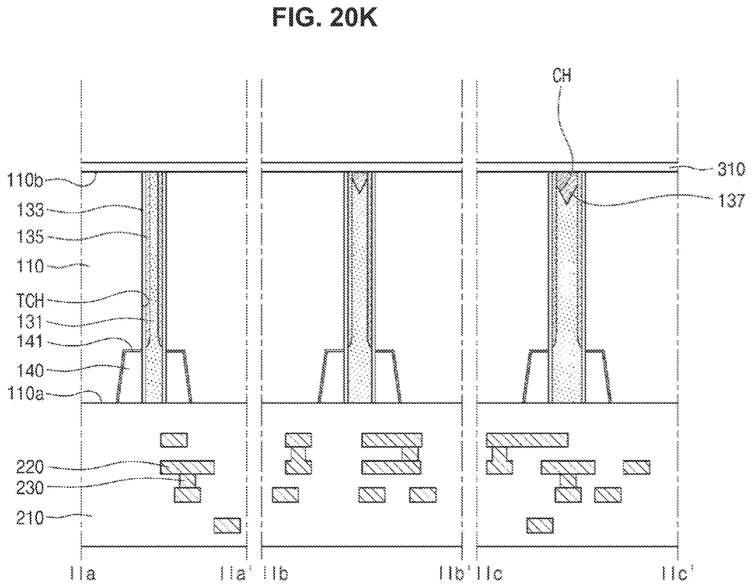

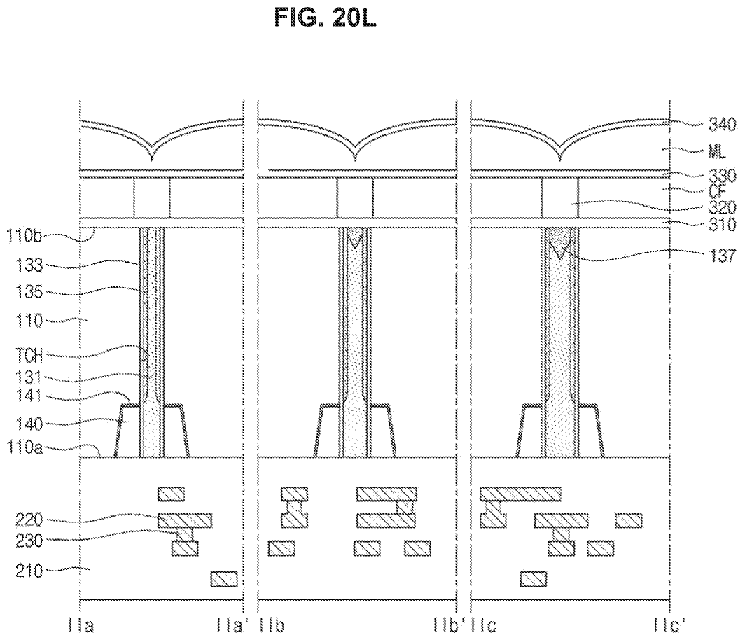

FIGS. 20A to 20L are cross-sectional views, sequentially illustrating a process of fabricating an image sensor according to an example embodiment, and corresponds to FIG. 12. For the sake of clarity, the process of fabricating an image sensor according to an example embodiment will be described with reference to FIGS. 11, 12, and 13A to 13C as an example, and redundant descriptions will be omitted.

Referring to FIG. 20A, a semiconductor substrate 110 may be provided with a first surface 110a and a second surface 110b opposing each other. A pad layer 141 and a shallow isolation layer 140 may be formed adjacent to each other on the first surface 110a of the semiconductor substrate 110, and may be buried in the semiconductor substrate 110. The pad layer 141 and the shallow isolation layer 140 may be formed of an insulating material, and may include a silicon oxide, a silicon nitride, and/or a silicon oxynitride. For example, the pad layer 141 may be formed of a silicon nitride and the shallow isolation layer 140 may be formed of a silicon oxide.

A trench TCH may be formed in the semiconductor substrate 110 on which the shallow isolation layer 140 is formed. The trench TCH may have different widths depending on regions. For example, the trench TCH may be formed to have first to third widths w1, w2, and w3 depending on a region in which a first device isolation layer 130a1 is to be formed, a region in which a second device isolation layer 130a2 is to be formed, and a region in which a third device isolation layer 130b is to be formed, and the first to third widths w1, w2, w3 may be sequentially larger values.

The trench TCH may extend into the semiconductor substrate 110 from the first surface 110a of the semiconductor substrate 110. The trench TCH may be formed by forming a mask pattern to define a region, in which the trench TCH is to be formed, corresponding to a region in which the device isolation layer 130 is to be formed, and etching the pad layer 141, the shallow isolation layer 140, and the semiconductor substrate 110 using the mask pattern.

When viewed in plan view, the trench TCH may be formed to have a shape in which lines extending in a first direction D1 or a second direction D2 parallel to a first surface 110a of the semiconductor substrate 110 intersect each other. The trench TCH may surround each pixel.

An insulating liner 133 may be formed on the semiconductor substrate 110 in which the trench TCH is formed. The insulating liner 133 may cover an internal wall of the trench TCH, and may conformally cover a surface of the semiconductor substrate 110 on which the shallow isolation layer 140 are formed.

Referring to FIG. 20B, a conductive liner 135 may be formed on the semiconductor substrate 110 on which the insulating liner 133 is formed. The conductive liner 135 may be formed by forming a layer to conformally cover an internal wall of the insulating liner 133 in the trench TCH and an upper surface of the semiconductor substrate 110, and then removing an upper portion of the layer formed within the trench TCH and a portion of the layer formed on the upper surface of the semiconductor substrate 110. The conductive liner 135 may include a semiconductor material doped with a first or second conductivity type impurity, such as polysilicon doped with boron or phosphorus.

The conductive liner 135 may be formed using at least one of a process of mixing a semiconductor material and an impurity to form a mixture and depositing the mixture (for example, low-pressure chemical vapor deposition (LPCVD) or plasma-enhanced chemical vapor deposition (PECVD)) and a process of depositing a semiconductor material and then implanting impurities (for example, ion injection, plasma doping, or gas phase doping). During such a process, an ion seed treatment may be performed using diisopropylamino silane (DIPAS) and/or hexachlorodisilane (HCDS) before depositing materials of the conductive liner 135 such that the conductive liner 135 may be conformally formed in the trench TCH.

Referring to FIG. 20C, a buried insulating pattern 131 may be formed in the trench TCH in which the conductive liner 135 is formed. The buried insulating pattern 131 may cover an upper surface of the semiconductor substrate 110. The buried insulating pattern 131 may be formed using a variety of processes such as atomic layer deposition (ALD), flowable chemical vapor deposition (FCVD), or physical vapor deposition (PVD).

The buried insulating pattern 131 may be formed of a material that is non-conductive and has improved gap-fill characteristics. For example, the buried insulating pattern may be formed of tonen silazene (TOSZ), undoped silicate glass (USG), borosilica glass (BSG), phosphosilaca glass (PSG), borophosphor silica glass (BPSG), plasma enhanced tetraethyl orthosilicate (PETEOS), fluoride silicate glass (FSG), or ozone-tetraethyl orthosilicate (O₃-TEOS). However, the material for the buried insulating pattern 131 is not limited thereto. For example, the buried insulating pattern 131 may include an oxide such as a silicon oxide, a silicon nitride, and/or a silicon oxynitride.

When the buried insulating pattern 131 is formed in the trench TCH, a void VD such as an air gap may be formed in the trench TCH. The void VD may or may not be formed within the trench TCH. In an example embodiment, a trench TCH for the second device isolation layer 130a2 that is wider than a trench TCH for the first device isolation layer 130al, and a trench TCH for the third device isolation layer 130b that is wider than a trench TCH for the second device isolation layer 130a2 are illustrated. The void VD may be formed to be larger when the width of the trench TCH is large. Accordingly, the void VD formed in the trench TCH for the third device isolation layer 130b may be larger than the void VD formed in the trench TCH for the second device isolation layer 130a2.

Referring to FIG. 20D, an upper portion of the first surface 110a of the semiconductor substrate 110 may be removed. The upper portion of the first surface 110a of the semiconductor substrate 110 may be removed through a chemical mechanical polishing (hereinafter referred to as “CMP”) process, an etching process, or both the CMP process and the etching process. As the etching process is performed, a portion of components on the semiconductor substrate 110 may be further removed.

In this case, the CMP process or the etching process may be performed until the shallow isolation layer 140 and the first surface 110a of the semiconductor substrate 110 are exposed to the outside. The pad layer 141 on the first surface 110a of the semiconductor substrate 110 may also be removed by the CMP process or the etching process. Accordingly, an upper surface of the shallow isolation layer 140, an upper surface of the insulating liner 133, and an upper surface of the buried insulating pattern 131 may be exposed to the outside, and the upper surface of the shallow isolation layer 140, an upper surface of the insulating liner 133, and an upper surface of the buried insulating pattern 131 may be coplanar.

Then, a photoelectric conversion region PD may be formed within the semiconductor substrate 110 of each pixel. As an example, the forming the photoelectric conversion region PD may include implanting second conductivity type (for example, N-type) impurities, different from first conductivity type (for example, P-type) impurities, into the semiconductor substrate 110.

Referring to FIG. 20E, a circuit interconnection layer may be formed on the first surface 110a of the semiconductor substrate 110. As an example, the circuit interconnection layer may form a gate pattern and a gate insulating layer on the first surface 110a. Additionally, an interlayer dielectric 210, a contact via 230, and conductive lines 220 may be formed on the first surface 110a.

Referring to FIG. 20F, the semiconductor substrate 110 may be flipped over (i.e., inverted) so that the second surface 110b faces up.

Referring to FIG. 20G, a thinning process may be performed on the second surface 110b of the semiconductor substrate 110, and a portion on a side of the second surface 110b of the semiconductor substrate 110 may be removed through the thinning process.

The second surface 110b of the semiconductor substrate 110 may be removed through a CMP process, an etching process, or both the CMP process and the etching process. The CMP process and/or the etching process may cause the second surface 110b of the semiconductor substrate 110 to be coplanar with upper surfaces of the conductive liner 135, the insulating liner 133, and the buried insulating pattern 131 of the device isolation layer 130. A void VD, such as an air gap, may be further included on an upper side of the buried insulating pattern 131. When a void VD is present, portions of the semiconductor substrate 110 and the conductive liner 135, the insulating liner 133, and the buried insulating pattern 131 may be removed to a point, at which the void VD is present, through the CMP process and/or the etching process.

Referring to FIG. 20H, portions of the insulating liner 133 and the buried insulating pattern 131 may be removed by etching. In this case, the buried insulating pattern 131 may be etched until an internal side surface of the conductive liner 135 corresponding to the second and third device isolation layers 131a2 and 130b is sufficiently exposed. In this case, the buried insulating pattern 131 may be etched to a depth of about 0 nm to about 2000 nm in a direction from the second surface 110b to the first surface 110a.

Etching of the buried insulating pattern 131 may be performed by wet etching or dry etching. In the case of wet etching, the buried insulating pattern 131 may be etched using hydrofluoric acid (HF), O₃/HF solution, or the like. In the case of dry etching, the buried insulating pattern 131 may be etched using radio-frequency (RF) plasma after a photolithography process. Alternatively, the buried insulating pattern 131 may be etched through a combination of wet etching and dry etching.

A hole CH, recessed from the second surface 110b, may be formed in a portion at which the insulating liner 133 and the buried insulating pattern 131 are etched. In the case of the second device isolation layer 130a2 and the third device isolation layer 130b in which the void VD is formed, the amount of etching the insulating liner 133 and the buried insulating pattern 131 may be larger. Accordingly, a size of the hole CH recessed from the second surface 110b may increase in a direction from the first device isolation layer 130a1 to the third device isolation layer 130b. In this case, the degree of etching may vary depending on an etching rate of a material for each component. When it is not desired for the hole CH to be formed deeply in the second device isolation layer 130a2, a depth of the hole CH may be controlled by, for example, performing a CMP process and/or an etching process on a point, at which a void VD is absent in the second device isolation layer 130a2, during a thinning process. In addition, the amount of etching the insulating liner 133 and buried insulation pattern 131 in the first to third device isolation layers 130a1, 130a2, and 130b may be controlled by controlling additional process conditions, or the like. For example, the amount of etching the buried insulation pattern 131 may also be controlled by controlling an etching time, an etchant, or the like.

Referring to FIG. 20I, a buried conductive pattern 137 may be formed on the second surface 110b of the semiconductor substrate 110 in which the holes CH are formed. The buried conductive pattern 137 may fill all of the holes CH formed on the second surface 110b of the semiconductor substrate 110 and may also cover an upper surface of the second surface 110b of the semiconductor substrate 110. The buried conductive pattern 137 may be formed using thin-film deposition, epitaxial growth, or impurity doping. For example, a conductive oxide such as indium tin oxide, metal, or the like, may be formed using physical/chemical deposition, and doped silicon may be formed through deposition or epitaxial growth (boron, phosphorus, or arsenic doping). The buried conductive pattern 137 may be brought into physical contact with the exposed side surface of the conductive liner 135 by completely filling the hole CH formed in the above-described etching process.

Referring to FIG. 20J, an upper portion of the semiconductor substrate 110, on which the buried conductive pattern 137 is formed, may be planarized through a CMP process, an etch-back process, or the like. In the planarization process, etching and/or CMP may be used in various ways depending on the material for the buried conductive pattern 137. In this case, the buried conductive pattern 137 should remain in the third device isolation layer 130b corresponding to the intersection portion 130b, among the first to third device isolation layers 130a1, 130a2, and 130b. According to example embodiments, the buried conductive pattern 137 may or may not remain in the first and second device isolation layers 130a1 and 130a2.

In an example embodiment, the second surface 110b of the semiconductor substrate 110 may be exposed through the above process, and upper surfaces of the first to third device isolation layers 130a1, 130a2, and 130b may be coplanar with the second surface 110b of the semiconductor substrate 110. The second surface 110b of the semiconductor substrate 110 may be coplanar with the upper surface of the first device isolation layer 130a1 (for example, the upper surface of the buried insulating pattern 131), and the upper surfaces of the second and third device isolation layers 131a2 and 130b (for example, the upper surface of the buried conductive pattern 137).

Referring to FIG. 20K, an upper insulating layer 310 may be formed on the second surface 110b of the semiconductor substrate 110 on which the first to third device isolation layers 130a1, 130a2, and 130b are formed. The upper insulating layer 310 may include an antireflective layer.

Referring to FIG. 20L, color filters CF, a fence pattern 320, an insulating layer 330, microlenses ML, a passivation layer 340, or the like, may formed on the semiconductor substrate 110 on which the upper insulating layer 310 is formed.

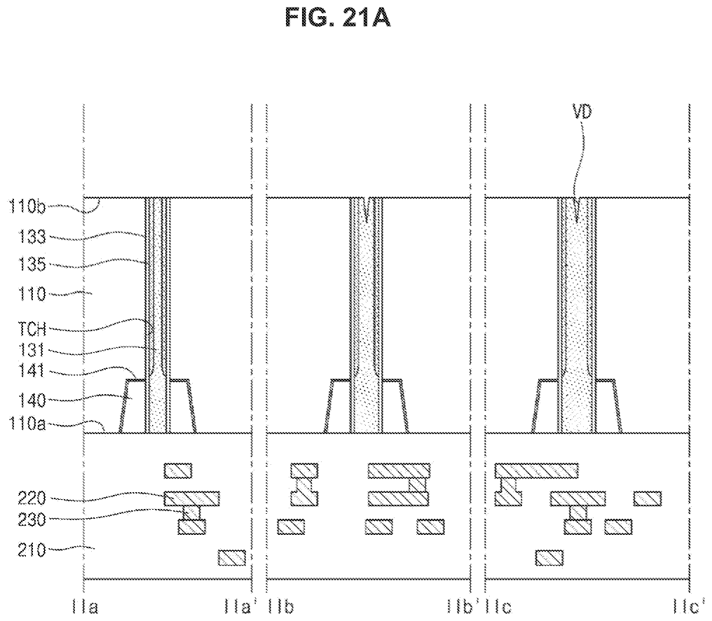

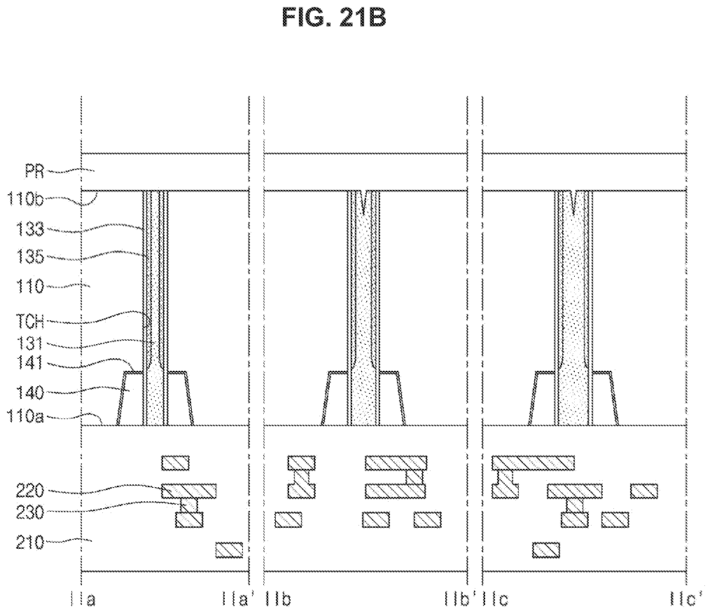

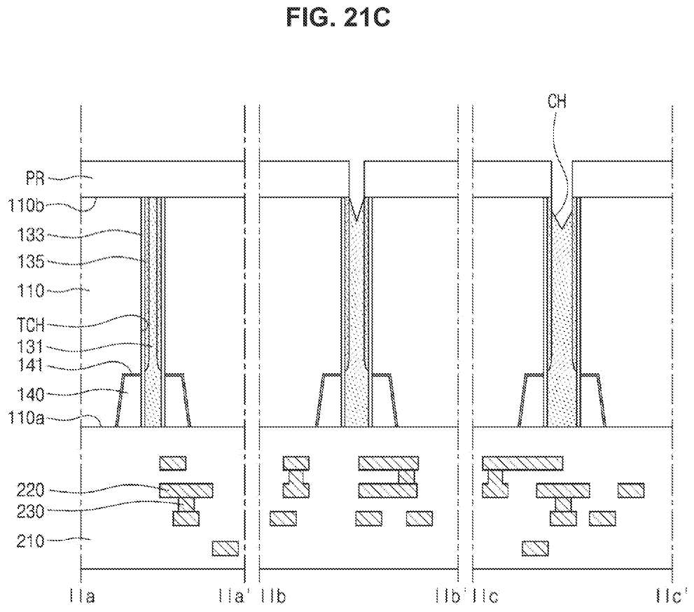

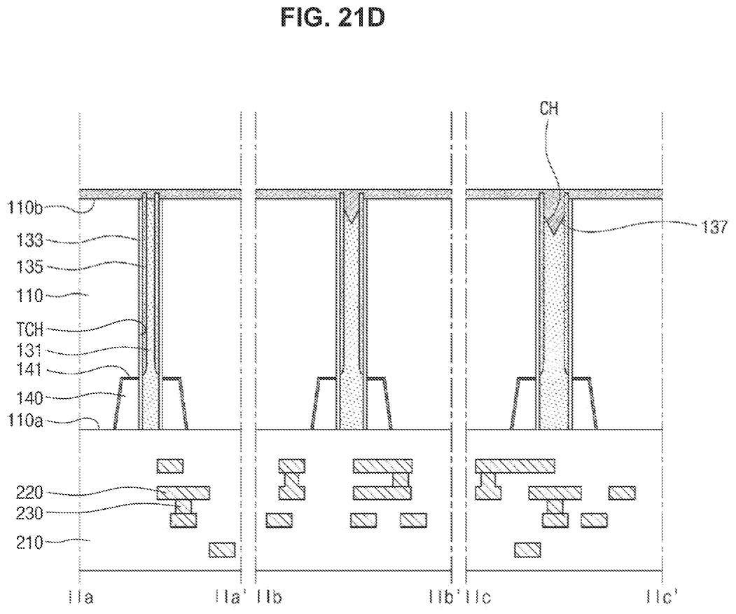

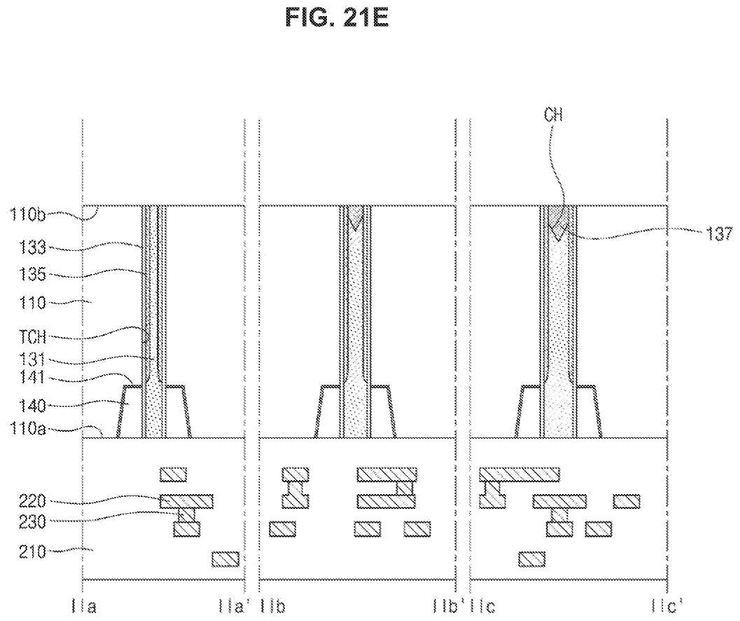

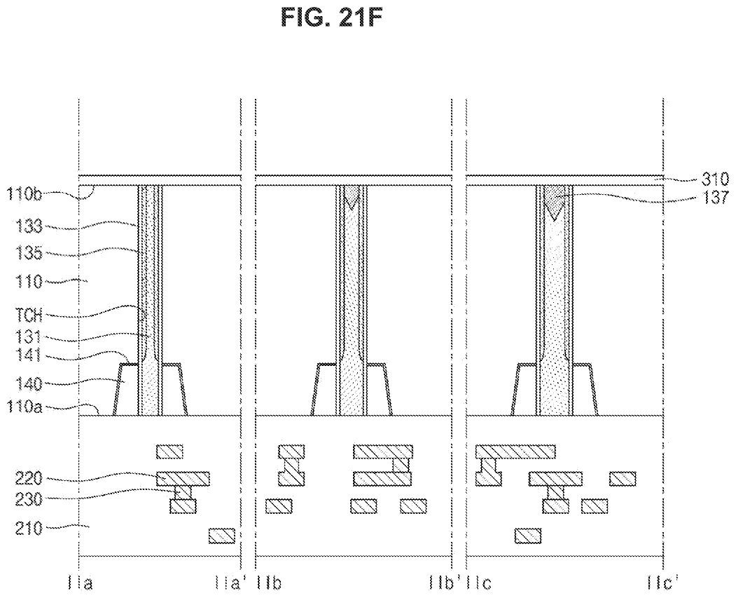

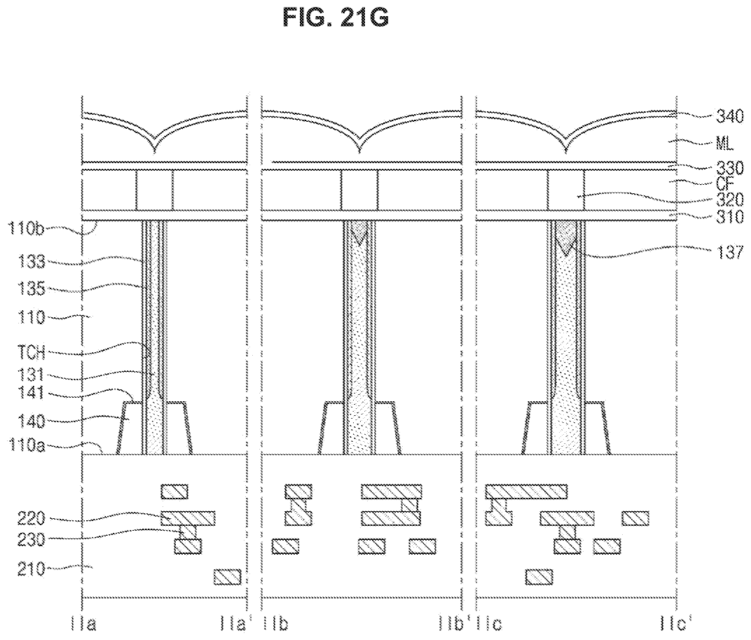

An image sensor according to an example embodiment may be formed through the above-described process. However, an example embodiment is not limited thereto, and the image sensor may be formed in other ways as well. FIGS. 21A to 21G are cross-sectional views illustrating a method of fabricating an image sensor according to an example embodiment. For the sake of clarity, the following description will focus on the differences between the description above. In an example embodiment, the processes illustrated in FIGS. 20A to 20F are performed in the same manner. Therefore, the description will start from the process after FIG. 20F.

Referring to FIG. 21A, a thinning process may be performed on the second surface 110b of the semiconductor substrate 110. A portion of the second surface 110b of the semiconductor substrate 110 may be removed by the thinning process. The thinning process causes the second surface 110b of the semiconductor substrate 110 to be coplanar with and the upper surfaces of the conductive liner 135, the insulating liner 133, and the buried insulating pattern 131 of the device isolation layer 130.

Referring to FIG. 21B, photoresist PR may be formed on the first surface 110a of the semiconductor substrate 110 on which the thinning process has been performed.

Referring to FIG. 21C, the photoresist PR may be exposed and developed using a mask such that a photoresist pattern is formed to expose upper surfaces of the second and third device isolation layers 131a2 and 130b. Then, an etching process may be performed using the photoresist pattern as a mask to etch and remove portions of the insulating liner 133 and the buried insulating pattern 131. The buried insulating pattern 131 may be etched until an internal side surface of the conductive liner 135 corresponding to the second and third device isolation layers 131a2 and 130b is sufficiently exposed. In this case, the buried insulating pattern 131 may be etched to a depth of approximately 0 to 2000 nm in a direction from the second surface 110b to the first surface 110a.

Etching of the buried insulating pattern 131 may be performed by wet etching or dry etching. In the case of wet etching, the buried insulating pattern 131 may be etched using HF, an O₃/HF solution, or the like. In the case of dry etching, the buried insulating pattern 131 may be etched using RF plasma after a photolithography process. Alternatively, the buried insulating pattern 131 may be etched through a combination of wet etching and dry etching.

A hole CH recessed from the second surface 110b may be formed in a portion in which the insulating liner 133 and the buried insulating pattern 131 are etched. In the case of the second device isolation layer 130a2 and the third device isolation layer 130b in which the void VD is formed, the amount of etching the insulating liner 133 and the buried insulating pattern 131 may be controlled by forming a photoresist pattern in various ways.

Referring to FIG. 21D, the photoresist pattern used as a mask may be removed, and a buried conductive pattern 137 may be formed on the second surface 110b of the semiconductor substrate 110 in which the holes CH are formed. The buried conductive pattern 137 may fill all of the holes CH, formed on the second surface 110b of the semiconductor substrate 110, to cover an upper surface of the second surface 110b of the semiconductor substrate 110. The buried conductive pattern 137 may be formed using thin-film deposition, epitaxial growth, or impurity doping. The buried conductive pattern 137 may be in brought into physical contact with the exposed side surface of the conductive liner 135 by completely filling the hole CH formed in the above-described etching process.

Referring to FIG. 21E, an upper portion of the semiconductor substrate 110, on which the buried conductive pattern 137 is formed, may be planarized by a CMP process, an etch-back process, or the like. In the planarization process, etching and/or CMP may be used in various ways depending on the material for the buried conductive pattern 137. In this case, the buried conductive pattern 137 should remain in the third device isolation layer 130b corresponding to the intersection portion 130b, among the first to third device isolation layers 130a1, 130a2, and 130b. According to example embodiments, the buried conductive pattern 137 may or may not remain in the first and second device isolation layers 130a1 and 130a2.

In an example embodiment, the second surface 110b of the semiconductor substrate 110 may be exposed through the above process, and upper surfaces of the first to third device isolation layers 130a1, 130a2, and 130b may be coplanar with the second surface 110b of the semiconductor substrate 110. The second surface 110b of the semiconductor substrate 110 may be coplanar with the upper surface of the first device isolation layer 130a1 (for example, the upper surface of the buried insulating pattern 131), and the upper surfaces of the second and third device isolation layers 131a2 and 130b (for example, the upper surface of the buried conductive pattern 137).

Referring to FIG. 21F, an upper insulating layer 310 may be formed on the second surface 110b of the semiconductor substrate 110 on which the first to third device isolation layers 130a1, 130a2, and 130b are formed. The upper insulating layer 310 may include an antireflective layer.

Referring to FIG. 21G, color filters, a fence pattern 320, an insulating layer 330, microlenses ML, a passivation layer, or the like, may formed on the semiconductor substrate 110 on which the upper insulating layer 310 is formed.

As set forth above, according to example embodiments, a conductive isolation layer with significantly reduced light absorption may be formed to significantly reduce optical loss of an image sensor. In addition, a negative bias may be applied to a device isolation layer to significantly reduce occurrence of defects such as dark current. As a result, photoelectric conversion efficiency of an image sensor according to example embodiments may be improved and deterioration of the image sensor may be prevented.

While example embodiments have been shown and described above, it will be apparent to those skilled in the art that modifications and variations could be made without departing from the scope of the present inventive concept as defined by the appended claims.

For example, in an example embodiment, a buried conductive pattern is described as being provided in an intersection of a device isolation layer, but the buried conductive pattern is not necessarily formed in all intersections of the device isolation layer. When the buried conductive pattern is sufficiently provided on a side portion of the device isolation layer secures electrical connection of the conductive liner, the buried conductive pattern in the intersection of the device isolation layer may be omitted.

What is claimed is:

1. An image sensor comprising:
a plurality of pixels;
a semiconductor substrate comprising a first surface and a second surface opposing the first surface;
a device isolation layer provided in a trench penetrating through the first surface and the second surface of the semiconductor substrate, and separating the plurality of pixels from each other; and
a microlens provided on the second surface,
wherein the device isolation layer comprises:
a buried insulating pattern penetrating through the first surface and the second surface;
an insulating liner between the buried insulating pattern and the semiconductor substrate;
a conductive liner between the insulating liner and the buried insulating pattern; and
a buried conductive pattern provided on at least a portion of the buried insulating pattern and contacting the conductive liner.

2. The image sensor of claim 1, wherein the buried conductive pattern is in direct physical contact with a side surface of the conductive liner.

3. The image sensor of claim 2, wherein the conductive liner surrounds a periphery of each of the plurality of pixels and extends between two adjacent pixels, among the plurality of pixels, and
wherein the buried conductive pattern is provided between the conductive liner of each of the two adjacent pixels to electrically and physically connect two separated conductive liners.

4. The image sensor of claim 3, further comprising a power circuit configured to provide a negative bias voltage to the buried conductive pattern.

5. The image sensor of claim 1, wherein the plurality of pixels are arranged in a matrix when viewed in plan view,
wherein the device isolation layer comprises:
side portions extending in a row direction and a column direction; and
intersection portions provided at regions in which the side portions intersect each other, and
wherein the buried conductive pattern is provided in any one or any combination of the side portions and the intersection portions.

6. The image sensor of claim 5, wherein one of the side portions comprises a first region having a first width and a second region having a second width greater than the first width, and
wherein the device isolation layer comprises:
a first device isolation layer provided in the first region;
a second device isolation layer provided in the second region; and
a third device isolation layer provided in the intersection portions.

7. The image sensor of claim 6, wherein the third device isolation layer comprises the buried conductive pattern.

8. The image sensor of claim 6, wherein in the third device isolation layer, the buried conductive pattern extends from the second surface to a point at a predetermined depth, and the buried insulating pattern extends from the first surface to the point at the predetermined depth, and
wherein along a direction perpendicular to the first surface, the buried insulating pattern has a length, greater than a length of the buried conductive pattern.

9. The image sensor of claim 6, wherein in the third device isolation layer, the buried conductive pattern extends from the second surface to a point at a predetermined depth, and the buried insulating pattern extends from the first surface to the point at the predetermined depth, and
wherein along a direction perpendicular to the first surface, the buried insulating pattern has a length, smaller than or equal to a length of the buried conductive pattern.

10. The image sensor of claim 6, wherein each of the second device isolation layer and the third device isolation layer comprises the buried conductive pattern.

11. The image sensor of claim 10, wherein in the second device isolation layer, the buried conductive pattern is spaced apart from the conductive liner adjacent thereto.

12. The image sensor of claim 10, wherein in the second device isolation layer, the buried conductive pattern is in direct physical contact with the conductive liner adjacent thereto.

13. The image sensor of claim 6, wherein each of the first to third device isolation layers comprises the buried conductive pattern.

14. The image sensor of claim 13, wherein along a direction perpendicular to the first surface, the buried conductive pattern extends farther in the second device isolation layer than in the first device isolation layer, and the buried conductive pattern extends farther in the third device isolation layer than in the second device isolation layer.

15. The image sensor of claim 1, wherein the buried conductive pattern comprises any one or any combination of doped polysilicon, metal, a metal oxide, a conductive organic material, or a conductive inorganic material.

16. The image sensor of claim 1, wherein the conductive liner comprises any one or any combination of metal, a metal oxide, or doped polysilicon.

17. The image sensor of claim 1, wherein the buried insulating pattern comprises any one or any combination of tonen silazene (TOSZ), undoped silicate glass (USG), borosilica glass (BSG), phosphosilaca glass (PSG), borophosphor silica glass (BPSG), plasma enhanced tetraethyl orthosilicate (PETEOS), fluoride silicate glass (FSG), or ozone-tetraethyl orthosilicate (O₃-TEOS), silicon oxide, silicon nitride, or silicon oxynitride.

18. An image sensor comprising:
a plurality of pixels arranged in a matrix;
a semiconductor substrate comprising a first surface and a second surface opposing the first surface, wherein the second surface is provided as a light-incident surface; and
a device isolation layer provided within a trench penetrating through the first surface and the second surface of the semiconductor substrate, and separating the plurality of pixels from each other,
wherein the device isolation layer comprises side portions, extending in a row direction and a column direction, and intersection portions provided at regions in which the side portions intersect each other, and
wherein each of the intersection portions comprises:
a buried insulating pattern extending from the first surface to the second surface;
an insulating liner between the buried insulating pattern and the semiconductor substrate;
a conductive liner between the insulating liner and the buried insulating pattern; and
a buried conductive pattern provided on the buried insulating pattern and contacting the conductive liner.

19. An image sensor comprising:
a plurality of pixels arranged in a matrix;
a semiconductor substrate comprising a first surface and a second surface opposing the first surface;
a device isolation layer provided within a trench penetrating through the first surface and the second surface of the semiconductor substrate to separate the plurality of pixels from each other, and comprising side portions and intersection portions, the side portions extending in a row direction and a column direction, and the intersection portions being in regions in which the side portions intersect each other; and
a microlens provided on the second surface,
wherein the device isolation layer comprises:
a buried insulating pattern penetrating through the first surface and the second surface;
an insulating liner between the buried insulating pattern and the semiconductor substrate;
a conductive liner between the insulating liner and the buried insulating pattern; and
a buried conductive pattern provided on at least a portion of the buried insulating pattern and contacting the conductive liner, and
wherein the buried conductive pattern is provided in at any one or any combination of the side portions and the intersection portions.

20. The image sensor of claim 19, wherein one of the side portions comprises a first region having a first width and a second region having a second width, greater than the first width, along a direction parallel to the first surface,
wherein the device isolation layer comprises:
a first device isolation layer provided in the first region;
a second device isolation layer provided in the second region; and
a third device isolation layer provided at the intersection portions, and wherein the third device isolation layer comprises the buried conductive pattern.
